(19) United States
(12) Patent Application Publication
(10) Pub. No.: US 2016/0112157 A1
(43) Pub. Date: Apr. 21, 2016

(54) Auto-Detection in Wireless Communications

(71) Applicants: Qinghua Li, San Ramon, CA (US); Xiaogang Chen, Beijing (CN); Yuan Zhu, Beijing (CN); Robert Stacey, Portland, OR (US); Rongzhen Yang, Shanghai (CN); Honggang Li, Beijing (CN)

(72) Inventors: Qinghua Li, San Ramon, CA (US); Xiaogang Chen, Beijing (CN); Yuan Zhu, Beijing (CN); Robert Stacey, Portland, OR (US); Rongzhen Yang, Shanghai (CN); Honggang Li, Beijing (CN)

(21) Appl. No.: 14/583,136

(22) Filed: Dec. 25, 2014

Related U.S. Application Data
(60) Provisional application No. 62/064,370, filed on Oct. 15, 2014.

(51) Int. Cl. H04L 1/00; H03M 13/09; G06F 11/10

(52) U.S. Cl. CPC H04L 1/0061; G06F 11/1004; H03M 13/09

(57) ABSTRACT

Embodiments of the disclosure provide auto-detection in wireless telecommunications. Certain embodiments provide or otherwise implement a specific sequence of bits and/or symbols for auto-detection. The specific sequence of bits can be embodied in or can include output codebits from an encoder in a communication device that can send a wireless transmission including the specific sequence. In one embodiment, the encoder can compute or otherwise generate cyclic redundancy checks (CRCs) or other types of validation checks at the communication device. The specific sequence can be determined using the payload of a packet frame. Both the manner in which the specific sequence is generated and the temporal order in which the specific sequence is received relative to other payload in the packet frame can provide specificity to the sequence.

### CROSS-REFERENCE TO RELATED APPLICATION

This application is related to and claims the benefit of U.S. Provisional Patent Application No. 62/064,370, filed on Oct. 15, 2014, which is hereby incorporated herein by reference in its entirety.

### BACKGROUND

In wireless communications, when receiving a packet, a wireless communication device typically first identifies the radio technology protocol version—e.g., Wi-Fi protocol version, such as IEEE 802.11a, IEEE 802.11n, IEEE 802.11ac, IEEE 802.11ax, or the like—in order to interpret subsequent information. Such identification may be referred to as auto-detection and can permit, at least in part, to synchronize the wireless communication device to an incoming wireless transmission prior to receiving the content (e.g., payload data, traffic, or the like) of a frame.

### BRIEF DESCRIPTION OF THE DRAWINGS

The accompanying drawings form an integral part of the disclosure and are incorporated into the present specification. The drawings illustrate example embodiments of the disclosure and, in conjunction with the description and claims, serve to explain at least in part various principles, features, or aspects of the disclosure. Certain embodiments of the disclosure are described more fully below with reference to the accompanying drawings. However, various aspects of the disclosure can be implemented in many different forms and should not be construed as limited to the implementations set forth herein. Like numbers refer to like elements throughout.

FIG. 1 illustrates an example of an operational environment in accordance with one or more embodiments of the disclosure.

FIG. 2 illustrates an example preamble structure of a packet for wireless transmissions in accordance with one or more embodiments of this disclosure.

FIGS. 3, 4, 5, 6, and 7 present examples of bit sequences in telecommunication in accordance with one or more embodiments of the disclosure.

FIG. 8 presents an example of a communication device in accordance with one or more embodiments of the disclosure.

FIG. 9 presents an example of a radio unit in accordance with one or more embodiments of the disclosure.

FIG. 10 presents an example of a computational environment in accordance with one or more embodiments of the disclosure.

FIG. 11 presents another example of a communication device in accordance with one or more embodiments of the disclosure.

FIGS. 12-13 present example methods for wireless communication in accordance with one or more embodiments of the disclosure.

### DETAILED DESCRIPTION

The disclosure recognizes and addresses, in one aspect, the issue of auto-detection in telecommunications, including wireless communications, wireline communications, a combination thereof, or the like. Certain conventional technologies for auto-detection in telecommunication typically entail hardware changes using new constellation size and power allocation, and/or new constellation rotations. More specifically, yet not exclusively, the disclosure provides devices, systems, techniques, and/or computer program products for auto-detection in wireless telecommunications, for example. As described in greater detail below, the computing devices, systems, platforms, methods, and computer program products disclosed herein provide auto-detection in telecommunications (wireless and/or wireline). Certain embodiments provide or otherwise implement a specific sequence of bits and/or symbols for auto-detection. The specific sequence of bits (which may be more colloquially referred to as “special sequence”) can be embodied in or can include output codebits from an encoder in a communication device that can send a wireless transmission including the specific sequence. More specifically, in one example, each bit in the specific sequence of bits can correspond to an output codebit from the encoder. In one embodiment, the encoder can compute or otherwise generate cyclic redundancy checks (CRCs) or other types of validation checks at the communication device. The specific sequence can be determined using the payload of a radio packet frame (or packet frame). The manner in which the specific sequence is generated and the temporal order (or “location”) in which the specific sequence is received relative to other payload in the packet frame provides specificity to the special sequence and can render it distinguishable from payload conveyed in packet according to legacy radio protocols, such as legacy Wi-Fi protocols. Therefore, a specific sequence of bits provided in accordance with aspects of this disclosure can embody a specifically or otherwise specially coded sequence of bits. In addition or in other embodiments, instead of introducing a new constellation and/or power allocation, the disclosure provides the specific bit sequence in the payload of a packet frame of a wireless transmission for a communication device (e.g., a receiver device (or receiver)) in order to detect a version of radio technology protocol—e.g., IEEE 802.11ax (or high-efficiency wireless local area network (HE WLAN or HEW)—utilized for wireless communications.

In certain embodiments, a specific bit sequence of the disclosure can be a cyclic redundancy check (CRC) sequence having a number of bits such that detection of a radio technology protocol can be performed, and the false alarm rate of the detection can be low. A false alarm can occur when a packet is received at a communication device and the associated CRC for a non-legacy radio protocol (e.g., IEEE 802.11ax) is validated by the communication device, and yet the received packet is actually legacy packet (e.g., an IEEE 802.11a packet, an IEEE 802.11n packet, or an IEEE 802.11ac packet). For instance, the information bit sequence of a legacy IEEE 802.11a packet may fortuitously pass the CRC validation of an IEEE 802.11ax packet. More specifically, in one example, the communication device (which may be operating as a receiver, for example) can compute a CRC bit sequence using a portion of a bit sequence in a packet received at the communication device. The computed or otherwise determined CRC bit sequence can be specific to the IEEE 802.11ax radio protocol. In addition, in one aspect, the communication device can compare bitwise the CRC bit sequence to another sequence of bits having certain bits at expected locations within the packet in accordance with an expected CRC bit sequence for the IEEE 802.11ax radio protocol. When each bit in the computed CRC bit sequence is the same as the expected CRC bit sequence, the communication device (e.g., a receiver) can determine that the received packet is an IEEE802.11ax packet even though the received packet is actually an IEEE 802.11a packet having content bits passing the proposed CRC check. Therefore, such an erroneous validation causes a false alarm event. False alarm events can be minimized, for example, by increasing the length of a CRC sequence from six bits to eight bits or 12 bits.

In certain implementations, a 12-bit CRC sequence can be generated using other payload bits in the first high-efficiency signal field (HE-SIG) symbols as input. In the present disclosure, a HE-SIG symbol corresponds to a symbol that contains physical layer header information and is added to the preamble of a packet in accordance with the IEEE 802.11ax protocol (or high efficiency wireless local area network (HEW) protocol). In such scenario, the false alarm rate can be below about 0.025%. Therefore, in one aspect, such a 12-bit CRC sequence can be sufficient to serve as identification (ID) for packets in a specific radio technology protocol (e.g., IEEE 802.11ax packets). Other CRC sequences having a different number of bits also can be utilized for auto-detection for HEW packets in accordance with aspects of this disclosure. For instance, in certain implementations, a 10-bit CRC can be introduced. In other implementations, for backward compatibility, 6-bit and 8-bit CRCs in legacy radio protocols, such as IEEE 802.11a and/or IEEE 802.11ac, can be utilized or leveraged to configure a specific auto-detection CRC sequence for HEW packets.

While various embodiments of the disclosure are illustrated in connection CRC sequences, it should be appreciated that the disclosure is not limited in that respect and other types of validation check sequences can be utilized. For example, parity check bits that can be or can include a linear combination of payload bits can be used as a validation check sequence for auto-detection in accordance with aspects of this disclosure. In one embodiment, the parity check bits can be generated in a similar manner as parity bits of linear block codes. When compared with conventional technologies for auto-detection in wireless telecommunications, certain embodiments of the disclosure may reduce implementation complexity by reducing or avoiding hardware adaptations or changes.

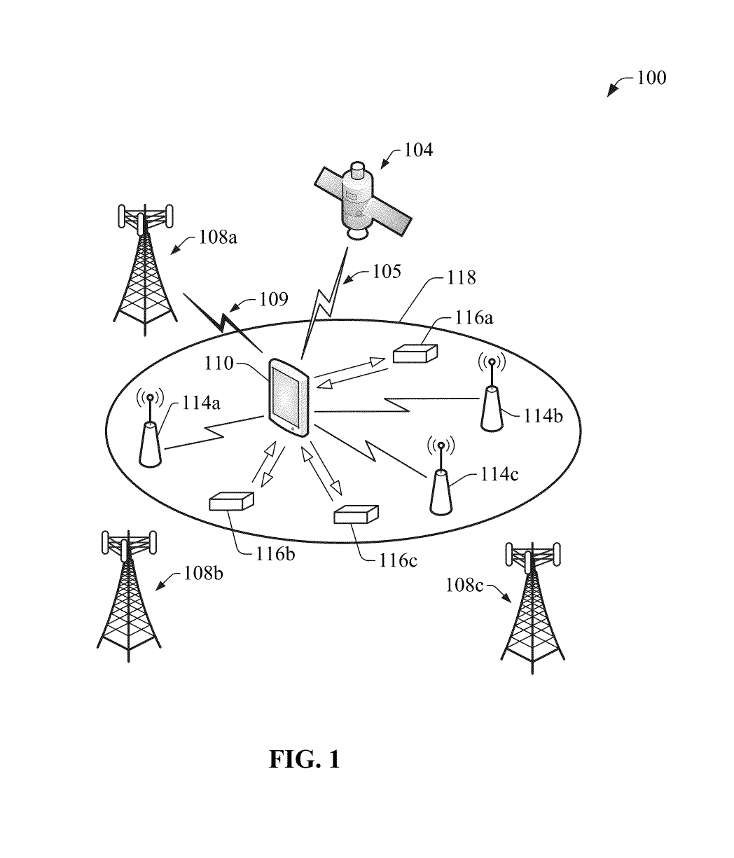

With reference to the drawings, FIG. 1 presents a block diagram of an example operational environment 100 for auto-detection in accordance with at least certain aspects of the disclosure. The operational environment 100 includes several telecommunication infrastructures and communication devices, which collectively can embody or otherwise constitute a telecommunication environment. More specifically, yet not exclusively, the telecommunication infrastructures can include a satellite system 104. As described herein, the satellite system 104 can be embodied in or can include a global navigation satellite system (GNSS), such as the Global Positioning System (GPS), Galileo, GLONASS (Globalnaya navigatsionnaya sputnikovaya sistema), BeiDou Navigation Satellite System (BDS), and/or the Quasi-Zenith Satellite System (QZSS). In addition, the telecommunication infrastructures can include a macro-cellular or large-cell system; which is represented with three base stations 108a-108c; a micro-cellular or small-cell system, which is represented with three access points (or low-power base stations) 114a-114c; and a sensor-based system—which can include proximity sensor(s), beacon device(s), pseudo-stationary device(s), and/or wearable device(s)—represented with functional elements 116a-116c. As illustrated, in one implementation, each of the transmitter(s), receiver(s), and/or transceiver(s) included in respective computing devices (such as telecommunication infrastructure) can be functionally coupled (e.g., communicatively or otherwise operationally coupled) with the wireless device 110 (also referred to as communication device 110) via wireless link(s) in accordance with specific radio technology protocols (e.g., IEEE 802.11a, IEEE 802.11ax, etc.) in accordance with aspects of this disclosure. For another example, a base station (e.g., base station 108a) can be functionally coupled to a wireless device 110 via an upstream wireless link (UL) and a downstream link (DL) (e g, links 109) configured in accordance with a radio technology protocol for macro-cellular wireless communication (e.g., 3^{rd} Generation Partnership Project (3GPP) Universal Mobile Telecommunication System (UMTS) or “3G,” “3G”; 3GPP Long Term Evolution (LTE), or LTE); LTE Advanced (LTE-A)). For yet another example, an access point (e.g., access point 114a) can be functionally coupled to the wireless device 110 via an UL and a DL configured in accordance with a radio technology protocol for small-cell wireless communication (e.g., femtocell protocols, Wi-Fi, and the like). For still another example, a beacon device (e.g., device 116a) can be functionally coupled to the wireless device 110 with a UL-only (ULO), a DL-only, or an UL and DL, each of such wireless links (represented with open-head arrows) can be configured in accordance with a radio technology protocol for point-to-point or short-range wireless communication (e.g., Zigbee, Bluetooth, or near field communication (NFC) standards, ultrasonic communication protocols, or the like).

In the operational environment 100, the small-cell system and/or the beacon devices can be contained in a confined area 118 that can include an indoor region (e.g., a commercial facility, such as a shopping mall) and/or a spatially-confined outdoor region (such as an open or semi-open parking lot or garage). The small-cell system and/or the beacon devices can provide wireless service to a device (e.g., wireless device 110) within the confined area 118. For instance, the wireless device 110 can handover from macro-cellular wireless service to wireless service provided by the small-cell system present within the confined area 118. Similarly, in certain scenarios, the macro-cellular system can provide wireless service to a device (e.g., the wireless device 110) within the confined area 118.

In certain embodiments, the wireless device 110, as well as other communication devices (wireless or wireline) contemplated in the present disclosure, can include electronic devices having computational resources, including processing resources (e.g., processor(s)), memory resources (memory devices (also referred to as memory), and communication resources for exchange of information within the computing device and/or with other computing devices. Such resources can have different levels of architectural complexity depending on specific device functionality. Exchange of information among computing devices in accordance with aspects of the disclosure can be performed wirelessly as described herein, and thus, in one aspect, the wireless device 110 also can be referred to as wireless communication device 110, wireless computing device 110, communication device 110, or computing device 110 interchangeably. Example of the computing devices that can communicate wirelessly in accordance with aspects of the present disclosure can include desktop computers with wireless communication resources; mobile computers, such as tablet computers, smartphones, notebook computers, laptop computers with wireless communication resources, Ultrabook™ computers; gaming consoles, mobile telephones; blade computers; programmable logic controllers; near field communication devices; customer premises equipment with wireless communication resources, such as set-top boxes, wireless routers, wireless-enabled television sets, or the like; and so forth. The wireless communication resources can include radio units (also referred to as radios) having circuitry for processing of wireless signals, processor(s), memory device(s), and the like, where the radio, the processor(s), and the memory device(s) can be coupled via a bus architecture.

The computing devices included in the example operational environment 100, as well as other computing devices contemplated in the present disclosure, can implement or otherwise leverage the auto-detection features described, including concatenated CRC calculation or determination. It should be appreciated that other functional elements (e.g., servers, routers, gateways, and the like) can be included in the operational environment 100. It should be appreciated that the auto-detection features of this disclosure can be implemented in any telecommunication environment including a wireline network (e.g., a cable network, an internet-protocol (IP) network, an industrial control network, any wide area network (WAN), a local area network (LAN), a personal area network (PAN), a sensor-based network, or the like); a wireless network (e.g., a cellular network (either small-cell network or macro-cell network), a wireless WAN (WWAN), a wireless LAN (WLAN), a wireless PAN (WPAN), a sensor-based network, a satellite network, or the like); a combination thereof; or the like.

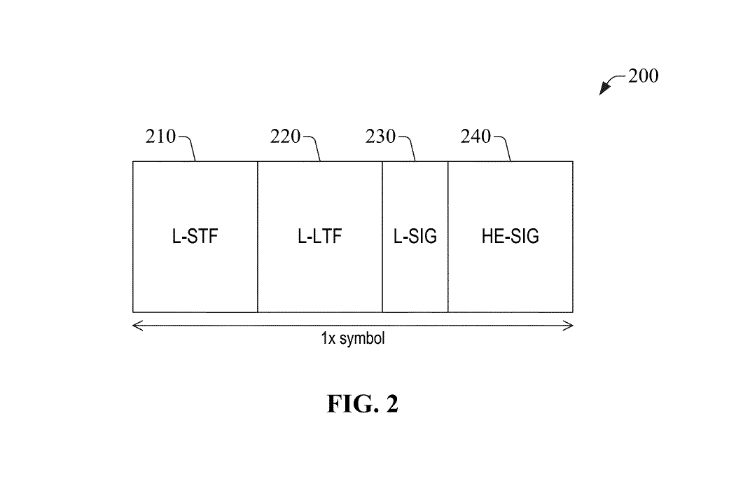

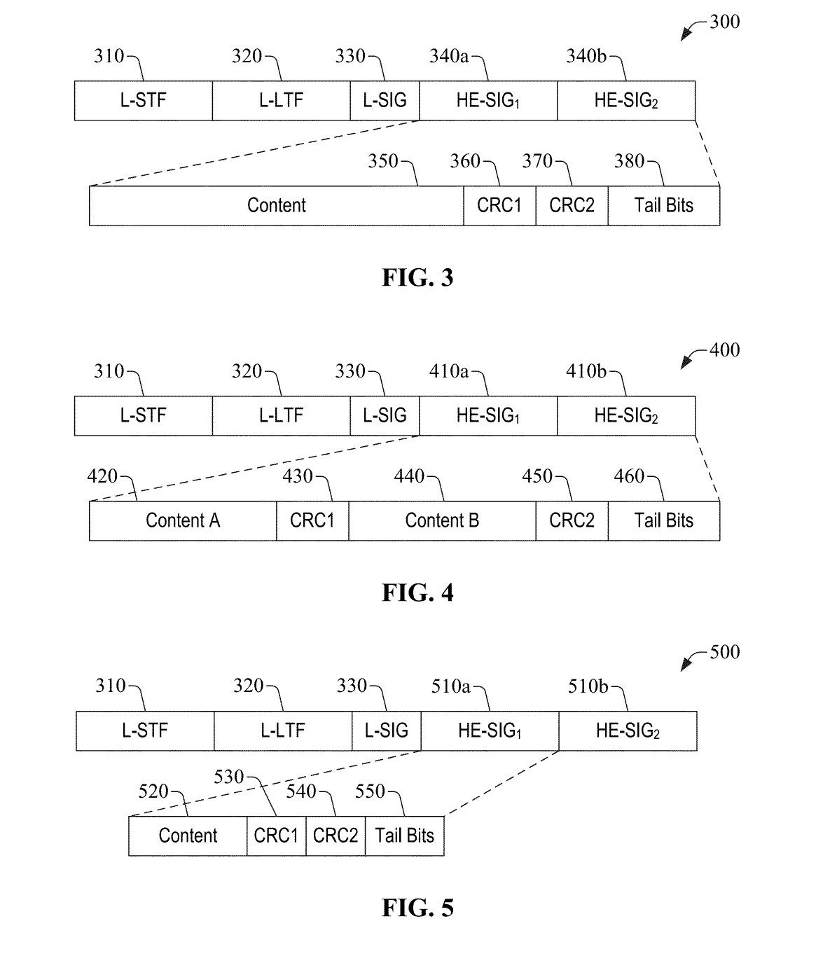

A communication device (e.g., communication device 110) that operates according to HEW can utilize or leverage a physical layer convergence protocol (PLCP) and related PLCP protocol data units (PPDUs) in order to transmit and/or receive wireless communications. In certain embodiments, communication devices of the disclosure can utilize or otherwise leverage a PPDU that can include a frame having a preamble structure as shown in FIG. 2. Specifically, FIG. 2 illustrates an example preamble structure 200 of a packet for wireless transmissions in accordance with one or more embodiments of the disclosure. The communication device can encode the information conveyed in the example preamble structure 200. As illustrated, the example preamble structure includes three legacy fields: legacy short training field (L-STF) 210, legacy long training field (L-LTF) 220, and legacy signal (L-SIG) field 230. Each of such fields can include one or more symbols. More specifically, the L-STF 220 can include 2 or more symbols, the L-LTF 220 can include 2 or more symbols, and the L-SIG field 230 can include one symbol. The L-SIG field 230 can be modulated according to binary phase-shift keying (BPSK). In addition, the example preamble structure 200 includes a high efficiency (HE) signal (HE-SIG) field 240. The HE-SIG field 240 is utilized in embodiments of the present disclosure to permit auto-detection of HEW packets, and can include one or more symbols. In certain embodiments, the HE-SIG field 240 can include at least two symbols (see, e.g., HE-SIG₁ 340a and HE-SIG₂ 340b depicted in FIG. 3).

With further reference to FIG. 2, it should be appreciated that the legacy fields 210, 220, and 230 can be processed (e.g., decoded) by legacy communication devices and by non-legacy communication devices that operate in accordance with a contemporaneous communication protocol (e.g., a radio communication protocol such as IEEE 802.11ax). The HE-SIG field 240 can be processed (e.g., decoded) and utilized by non-legacy devices. In certain embodiments, the information (e.g., data, metadata, and/or signaling) contained in at least one of the illustrated fields can be encoded and/or modulated in accordance with any type of modulation and coding scheme (MCS). As described in greater detail hereinafter in connection with FIGS. 3-7, one or more symbols (e.g., orthogonal frequency division multiplexing (OFDM) symbols) included in the HE-SIG field 240 can include specific sequences of bits that permit or otherwise facilitate auto-detection in HEW packets. A portion of the subcarriers of an OFDM symbol of the HE-SIG field 240 (such as first received symbol HE-SIG₁) can be utilized to repeat a portion of the symbol(s) in the L-SIG field 230. To that end, for example, signals on the even subcarriers that are included in such OFDMA symbol of the HE-SIG field 240 can replicate the portion of the symbol(s) in the L-SIG field 230. Such repetition can permit increasing the reliability for decoding at least some information, such as the length field in L-SIG field 230. Therefore, content conveyed in the HE-SIG field 240 can be directed to be used in HE-SIG, with exception of those subcarriers that repeat the signals in symbol(s) of the L-SIG field 230. It should be appreciated that a communication device (e.g., communication device 110) can encode or otherwise process the L-STF 210, the L-LTF 220, the L-SIG field 240, and the HE-SIG field 240 as described herein, including the described repetition of signals. It should further be appreciated that after processing of the HE-SIG field 240 in the preamble of a packet, a communication device (e.g., communication device 110) can process training signal conveyed in subsequent fields in a packet, such as the high-efficiency short training field (HE-STF) (not depicted) in order to implement proper beam forming or other types of operations necessary for telecommunication (wireless or otherwise).

FIG. 3 presents an example of a bit sequence in an example preamble 300 of a packet in accordance with one or more embodiments of the disclosure. The preamble includes an L-STF 310, and L-LTF 320, and a L-SIG field 330. In addition, the preamble 300 includes a high-efficiency signal (HE-SIG) field including a first symbol HE-SIG₁ 340a and a second symbol HE-SIG₂ 340b. As illustrated, in one example, such symbols can be the first two symbols of the HE-SIG field. Each of the symbols HE-SIG₁ 340a and HE-SIG₂ 340b can have, for example, the same symbol duration as the IEEE 802.11a L-SIG field 330 such that the false alarm rate can be minimized or otherwise mitigated for communication devices (e.g., receivers) operating according to IEEE 802.11n and/or IEEE 802.11ac. In certain embodiments, the symbol duration and/or the cyclic prefix (CP) duration of HE-SIG₁ 340a and/or HE-SIG₂ 340b can be greater than that of the legacy IEEE 802.11a L-SIG 330. The constellations of the two symbols (e.g., HE-SIG₁ 340a and HE-SIG₂ 340b) can be configured in numerous ways. In one embodiment, the constellations are the same as in IEEE 802.11a with normal BPSK constellation. In another embodiment, the constellations can be the same as in IEEE 802.11ac, with HE-SIG₁ 340a modulated according to normal BPSK and HE-SIG₂ 340b modulated according to a rotated BPSK (or quadrature BPSK (Q-BPSK)). As such, a legacy communication device, or a component therein, can detect the BPSK constellation and the subsequent Q-BPSK constellation, and can process the IEEE 802.11ax preamble according to legacy IEEE 802.11ac procedures instead of IEEE 802.11n procedures. The legacy communication device can then release the automatic gain control (AGC) for the very high throughput (VHT) STF (VHT-STF) in IEEE 802.11ac. In view that for channel reservation, IEEE 802.11ac receiver procedures can be more reliable than IEEE 802.11n receiver procedures, it may be desirable to utilize or otherwise leverage IEEE 802.11ac constellations in the 802.11ax preamble.

In the embodiment shown in FIG. 3, the symbol HE-SIG₁ 340a and the symbol HE-SIG₂ 340b can be encoded jointly by a transmitter (e.g., a communication device that sends a wireless transmission). As illustrated, the transmitter can encode HE-SIG₁ 340a and HE-SIG₂ 340b to include multiple bits. Specifically, in certain embodiments, the bits in symbols HE-SIG₁ 340a and HE-SIG₂ 340b can include a content portion 350 (which can include one or more fields); a CRC1 360 and a CRC2 370; and tail bits 380. The content portion 350 (or content 350) can include format information, such as channel bandwidth (e.g., 20 MHz, 40 MHz, 80 MHz, or 160 MHz), modulation and coding scheme (MCS), number of symbols of the HE-SIG field 240, and the like. In certain embodiments, the content portion 350 can include any number of bits in the range from 8 bits to 40 bits. In addition or in other embodiments, a portion of the OFDM subcarriers that convey the content portion 350 can be utilized to repeat a portion of the symbol(s) in the L-SIG field 330. For instance, signals on even OFDM subcarriers that are included in the content portion 350 can replicate the portion of the symbol(s) in the L-SIG field 330. Such repetition can permit increasing the reliability for decoding at least some information, such as the length field in L-SIG field 330. Therefore, some of the content portion 350 can be directed to be used in HE-SIG, with exception of those subcarriers that repeat the signals in the symbol(s) of the L-SIG field 330. The communication device (e.g., communication device 110) that transmits the example preamble 400 can encode or otherwise process HE-SIG₁ 340a and HE-SIG₂ 340b as described herein, including the described repetition of signals.

In addition or other embodiments, the tail bits 380 can include a specific number of “0” bits (e.g., six “0” bits). In one embodiment, the transmitter can utilize or otherwise rely on a normal convolutional code in order to encode HE-SIG₁ 340a and HE-SIG₂ 340b jointly. Therefore, in one aspect, the tail bits 380 can permit terminating the encoder. In other embodiments, the transmitter can utilize or otherwise rely on a tail biting convolutional code in order to encode HE-SIG₁ 340a and HE-SIG₂ 340b jointly. Accordingly, in such embodiments, the tail bits 380 can be removed from the jointly encoded HE-SIG₁ 340a and HE-SIG₂ 340b.

Further or in yet other embodiments, each of the CRC1 360 and the CRC2 370 can include one of 6 bits or 8 bits. It should be appreciated that IEEE 802.11a utilizes 6 bit CRC and IEEE 802.11ac utilizes 8 bit CRC. In other implementations, more than 8 bits or less than 6 bits can be utilized for each of the HE-SIG₁ 340a and HE-SIG₂ 340b. As described herein, the size of the net CRC sequence, e.g., CRC1 360 and CRC2 370 in FIG. 3, can determine a false alarm rate of auto-detection. As such, in one example, each of CRC1 360 and CRC2 370 can include 6 bits, which can result in 12 bits for CRC, providing a satisfactory false alarm rate (e.g., about 0.025% or similar).

In certain embodiments, a communication device (e.g., access point 114a) can determine or otherwise compute CRC1 360 using at least a portion of the content 350 as input. In addition or in other embodiments, the computing device can determine or otherwise compute the CRC2 370 using the at least a portion of the content 350 in reversed order. In yet other embodiments, the communication device can use different subsets of the content 350 as input in order to compute or otherwise determine CRC1 360 and CRC2 370. For example, the communication device can compute or otherwise determine CRC1 360 using even bits of the content 350, and can compute or otherwise determine CRC2 370 using odd bits of the content 350.

In certain implementations, a mask may be added to the CRCs in accordance with this disclosure. To that end, a communication device can implement (e.g., compute) a bitwise XOR operation between each bit in the mask and each bit in a CRC. In one example, a mask sequence can be {1, 0, 1, 1} and the CRC sequence can be {0, 1, 1, 0}. Therefore, after implementation of a bitwise XOR operation, the masked CRC sequence is {1, 1, 0, 1}. For another example, the communication device can utilize a basic service set identification (BSSID) as a mask for masking CRC1 360 and CRC2 370. Some or all the bits corresponding to the BSSID can be utilized for masking, e.g., 10 bits out of 14 bits can be used. In the alternative or in other implementations, the communication device can perform the masking operation separately for CRC1 360 and CRC2 370. More specifically, in one example, the communication device can mask the CRC1 360 with a portion of the BSSID used as a mask. In addition, the communication device can utilize at least a portion of the content 350 and the masked CRC1 360 as the input to compute or otherwise determine the CRC2 370. After the CRC2 370 is computed or otherwise determined, the communication device can utilize a second portion of the BSSID as second mask on CRC2 370.

It should be appreciated that, in certain implementations, CRC1 360 and CRC2 370 can be encoded, primarily, for reusing legacy components in a communication device (either a transmitter or receiver, or both). Yet, in certain embodiments, instead of two short CRCs (such as CRC1 360 and CRC2 370), one long CRC may be used. The long CRC can be defined for IEEE 802.11ax protocols and can include, for example, 8 bits, 10 bits, or 12 bits. The long CRC may be masked (e.g. by a BSSID). As such, for example, instead of the CRC1 360 and the CRC2 370 each having six bits, the CRC1 360 and the CRC2 370 can be merged into a single CRC having 12 bits. It should be appreciated that, as described herein, HE-SIG₁ 340a and HE-SIG₂ 340b can be encoded jointly or otherwise collectively, as a whole.

Masking a CRC, such as CRC1 360 and/or CRC2 370, with a BSSID or other types of mask can provide certain efficiencies. Specifically, in one example, masking can reduce communication overhead as the content in the mask and the CRC can be transmitted over the same resource (e.g., time period, logical channel, field, etc.). For instance, in a scenario in which a long 12-bit CRC (e.g., merged 6-bit CRC1 360 and/or 6-bit CRC2 370) is masked with the BSSID, there is no need for additional 12 bits in the content (e.g., content 350) transmitted in the preamble in order to convey the BSSID. As a tradeoff to such an efficiency, masking the CRC can cause a communication device receiving the masked CRC to not validate the masked CRC for verifying the HE-SIG reception because the communication device (e.g., a receiver in this scenario) may not have access to the mask utilized for masking the CRC. Therefore, in certain implementations, the masking may not be suitable for an advertisement packet, such as a beacon. One example approach to address the issues with advertisement packets in the presence of masking can include the following: Multiple masks may be introduced. For example, an advertisement packet (e.g., a broadcast packet) can be either not masked or masked by one of the multiple masks, such as all zeros (e.g., “0000000000”) or all ones (e.g., “1111111111”). In addition or in the alternative, a cell (or group) specific packet may be masked, for example, by the cell (or group) ID. As such, the communication device receiving a packet can attempt to unmask (e.g., detect or otherwise decode) the received packet using one or more predetermined masks (e.g., BSSID, Cell ID, Group ID, “0000000000,” “1111111111,” or the like). Detection with the correct mask can permit the decoding of the received masked packet.

FIG. 4 presents an example of a bit sequence in an example preamble 400 of a packet in accordance with one or more embodiments of the disclosure. Similar to other preambles of the disclosure, the preamble 400 includes an L-STF 310, and L-LTF 320, and a L-SIG field 330. In addition, the preamble 400 includes a HE-SIG field (not depicted) including a first symbol HE-SIG₁ 410a and a second symbol HE-SIG₂ 410b. In one example, such symbols can be the first two symbols of the HE-SIG field 240 shown in FIG. 2. A communication device that transmits the example preamble 400 can encode HE-SIG₁ 410a and HE-SIG₂ 410b to include multiple bits. Specifically, in certain embodiments, the bits in symbols HE-SIG₁ 410a and HE-SIG₂ 410b can include a content portion 420 (also referred to as content A 420), which can include one or more fields; a CRC1 430; a content portion B 440 (also referred to as content B 440), which can include one or more fields; a CRC2 450; and tail bits 460. Each of the symbols HE-SIG₁ 410a and HE-SIG₂ 410b can have, for example, the same symbol duration and cyclic prefix (CP) duration as the IEEE 802.11a legacy signal field 330 such that the false alarm rate can be minimized or otherwise mitigated for communication devices (e.g., receivers) operating according to IEEE 802.11n and/or IEEE 802.11ac. In certain embodiments, the symbol duration or the CP duration of HE-SIG₁ 410a and/or HE-SIG₂ 410b can be greater than that of the legacy IEEE 802.11a L-SIG filed 330. The constellations of the symbols HE-SIG₁ 410a and HE-SIG₂ 410b can be configured in numerous ways. In one embodiment, the constellations are the same as in IEEE 802.11a with normal BPSK constellation. In another embodiment, the constellations are the same as in IEEE 802.11ac, with one of HE-SIG₁ 410a or HE-SIG₂ 410b modulated according to normal BPSK and the other one of such symbols being modulated according to a rotated BPSK (or quadrature BPSK (Q-BPSK)).

In certain embodiments, the content A 420 can include any number of bits in the range from 8 bits to 40 bits, although more or less bits can be contemplated. In addition or in other embodiments, a portion of the OFDM subcarriers that convey the content A 420 can be utilized to repeat a portion of the symbol(s) in the L-SIG field 330. For instance, signals on even OFDM subcarriers that are included in the content A 420 can replicate the portion of the symbol(s) in the L-SIG field 330. Such repetition can permit increasing the reliability for decoding at least some information, such as the length field in L-SIG field 330. Therefore, some of the content portion 350 can be directed to be used in HE-SIG, with exception of those subcarriers that repeat the signals in the symbol(s) of the L-SIG field 330. The communication device (e.g., communication device 110) that transmits the example preamble 400 can encode or otherwise process HE-SIG₁ 410a as described herein, including the described repetition of signals.

As described herein, in the example preamble 400, a communication device (e.g., a transmitter) generating a packet can insert content B 440 (e.g., formatting information) between CRC1 430 and CRC2 450. As illustrated, content A 420 also is included prior to CRC1 430. The communication device can compute or otherwise determine CRC2 450 using content A 420, CRC1 430, and content B 440 as the input. In the alternative or in additional implementations, the CRC2 450 can be computed using content B 440 as input. As described herein, each of CRC1 430 and CRC2 450 can include multiple bits (e.g., 4 bits, 6 bits, 8 bits, 10 bits, 12 bits, or the like), and at least one of CRC1 430 or CRC2 450 can be masked in accordance with aspects described herein. It should be appreciated that in implementations in which each of CRC1 430 and CRC2 450 include less than 8 bits, such CRC sequences can be encoded, in one aspect, for reusing legacy components in a communication device (either a transmitter or receiver, or both). In the alternative, in implementation in which one or more of CRC1 430 and CRC2 450 can be embodied in a long CRC sequence, the long CRC sequence can be defined for IEEE 802.11ax protocols and can include, for example, 8 bits, 10 bits, or 12 bits. The long CRC may be masked (e.g. by a BSSID).

In certain implementations, for early termination of auto-detection, a communication device can compute or otherwise determine CRC1 430 using content A 420, and the codebits of CRC1 430 and content A 420 can be encoded within HE-SIG₁ 410a symbol. In one of such implementations, if at another communication device receiving the preamble 400 the CRC1 430 fails to be validated, such a communication device can abort the reception of additional information and, thus, may not decode the HE-SIG₂ 410b symbol in order to save power and/or to receive another packet over the air. In the alternative, if the communication device receiving the preamble 400 validates the CRC1 430, such a communication device can continue receiving information and can determine that the information is to be received according to an IEEE 802.11ax packet.

In addition, the communication device (e.g., a transmitter) that jointly encodes HE-SIG₁ 410a and HE-SIG₂ 410b can include symbols HE-SIG₁ 340a and HE-SIG₂ 340b can include tail bits 460 in the example preamble 400. The tail bits 460 can include a specific number of “0” bits (e.g., six “0” bits). In one embodiment, such a communication device can utilize or otherwise rely on a normal convolutional code in order to encode HE-SIG₁ 410a and HE-SIG₂ 410b jointly. Therefore, in one aspect, the tail bits 460 can be included to terminate the encoder. In other embodiments, the communication device can utilize or otherwise rely on a tail biting convolutional code in order to encode HE-SIG₁ 410a and HE-SIG₂ 410b jointly. Accordingly, in such embodiments, the tail bits 460 can be removed from the jointly encoded HE-SIG₁ 410a and HE-SIG₂ 410b.

FIG. 5 presents an example of a bit sequence in an example preamble 500 of a packet in accordance with one or more embodiments of the disclosure. Similar to other preambles of the disclosure, the preamble 500 includes an L-STF 310, and L-LTF 320, and an L-SIG field 330. In addition, the preamble 500 includes a HE-SIG field (not depicted) including a first symbol HE-SIG₁ 510a and a second symbol HE-SIG₂ 510b. In one example, such symbols can be the first two symbols of the HE-SIG field shown in FIG. 2. A communication device that transmits the example preamble 500 can encode HE-SIG₁ 510a and HE-SIG₂ 510b, each having multiple bits similarly configured or otherwise arranged. Specifically, in certain embodiments, the bits in the symbol HE-SIG₁ 510a can include a content portion 520 (also referred to as content 520), which can include one or more fields; a CRC1 530 and a CRC2 540; and tail bits 550. The tail bits 550 can include a specific number of “0” bits (e.g., six “0” bits).

Each of the symbols HE-SIG₁ 510a and HE-SIG₂ 510b can have, for example, the same symbol duration as the IEEE 802.11a legacy signal field 330 such that the false alarm rate can be minimized or otherwise mitigated for communication devices (e.g., receivers) operating according to IEEE 802.11n and/or IEEE 802.11ac. In certain embodiments, the symbol duration or the CP duration of HE-SIG₁ 510a and/or HE-SIG₂ 510b may be greater than that of the legacy 802.11a legacy SIGNAL filed 330. The constellations of the symbols HE-SIG₁ 510a and HE-SIG₂ 510b can be configured in numerous ways. In one embodiment, the constellations are the same as in IEEE 802.11a with normal BPSK constellation. In another embodiment, the constellations are the same as in IEEE 802.11ac, with one of HE-SIG₁ 510a or HE-SIG₂ 510b modulated according to normal BPSK and the other according to a rotated BPSK (or quadrature BPSK (Q-BPSK)).

In certain embodiments, the content 520 can include any number of bits in the range from 8 bits to 40 bits, although more or less bits also can be contemplated. In addition or in other embodiments, a portion of the OFDM subcarriers that convey the content 520 can be utilized to repeat a portion of the symbol(s) in the L-SIG field 330. For instance, signals on even OFDM subcarriers that are included in the content 520 can replicate the portion of the symbol(s) in the L-SIG field 330. Such repetition can permit increasing the reliability for decoding at least some information, such as the length field in L-SIG field 330. Therefore, some of the content portion 350 can be directed to be used in HE-SIG, with exception of those subcarriers that repeat the signals in the symbol(s) of the L-SIG field 330. The communication device (e.g., communication device 110) that transmits the example preamble 500 can encode or otherwise process HE-SIG₁ 510a as described herein, including the described repetition of signals.

As illustrated, a communication device encoding the HE-SIG₁ 510a symbol can include content 520, CRC1 530, CRC2 540, and tail bits 550 (e.g., a sequence of six “0” bits). Similar to content 350, the content 520 can include formatting information. The CRC1 530 and the CRC2 540 can form a long CRC that is included in the first HE-SIG symbol 510a. Such a long CRC can permit more reliable auto-detection and can reduce auto-detection latency because of the larger number of bits for CRC with respect to an individual CRC, such as CRC1 430 or CRC2 450. After decoding the HE-SIG₁ 510a symbol, the receiver (e.g., the communication device receiving a wireless transmission) can determine if the packet is an IEEE 802.11ax packet—e.g., a validated CRC indicates a HEW packet and a non-validated CRC indicates a legacy packet. Therefore, in one aspect, the receiver can have additional 4 μs preparation time for receiving an IEEE 802.11ax packet or an IEEE 802.11ac packet because the HE-SIG2 510b need not be received or decoded for auto-detection in accordance with aspects described herein. For example, the receiver may need to release the AGC for an IEEE 802.11ac packet after the HE-SIG₂ 510b symbol after the L-SIG field 330 if the constellations for HE-SIG₁ and HE-SIG₂ 510 are the same as in IEEE 802.11ac.

In certain embodiments, the CRC1 530 can have 6 bits or 8 bits, and the CRC2 540 can have 6 bits or 8 bits, and the communication device that encodes or otherwise generates the preamble 500 can replace the CRC1 530 and CRC2 540 can with one long CRC (e.g., a long sequence of CRC bits). As described herein, masking may be applied to the long CRC or at least one of CRC1 530 or CRC2 540 in order to reduce communication overhead.

It should be appreciated that, CRC1 360 and CRC2 370 can be encoded, in one aspect, for reusing legacy components in a communication device (either a transmitter or receiver, or both). It should further be appreciated that, in the embodiment shown in FIG. 5, the HE-SIG field, which includes HE-SIG₁ 510a and HE-SIG₂ 510b, is intended to have a strong CRC, or other types of integrity verification. Thus, in one implementation, CRC1 530 and CRC2 540 can be utilized to form a single long CRC sequence, as described herein. The long CRC can be defined for IEEE 802.11ax protocols and can include, for example, 8 bits, 10 bits, or 12 bits. It should further be appreciated that, in some embodiments, the AGC included in a communication device receiving a wireless transmission formatted according to aspects of the disclosure can be released at a suitable time after the HE-SIG₁ 510a symbol is processed by such a communication device.

In addition, the communication device (e.g., a transmitter) that encodes HE-SIG₁ 510a can utilize or otherwise rely on a normal convolutional code in order to encode HE-SIG₁ 510a and, in one aspect, the tail bits 550 can be included to terminate the encoder. In other embodiments, the communication device can utilize or otherwise rely on a tail biting convolutional code in order to encode HE-SIG₁ 510a. Accordingly, in such embodiments, the tail bits 460 can be removed from HE-SIG₁ 510a (and/or HE-SIG₂ 510b).

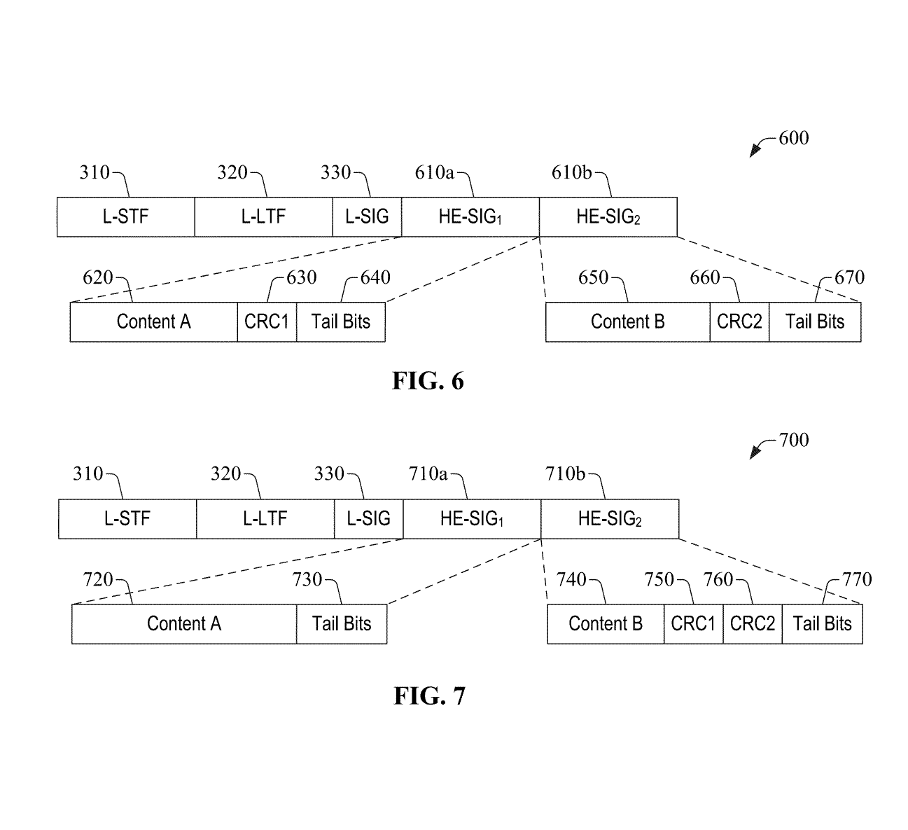

FIG. 6 presents an example of a bit sequence in an example preamble 600 of a packet in accordance with one or more embodiments of the disclosure. Similar to other preambles of the disclosure, the example preamble 600 includes an L-STF 310, and L-LTF 320, and an L-SIG field 330. In addition, the example preamble 600 includes a HE-SIG field (not depicted) including a first symbol HE-SIG₁ 610a and a second symbol HE-SIG₂ 610b. In one example, such symbols can be the first two symbols of the HE-SIG field shown in FIG. 2. A communication device that transmits the example preamble 600 can encode HE-SIG₁ 610a and HE-SIG₂ 610b, each having multiple bits similarly configured or otherwise arranged. Specifically, in certain embodiments, the bits in the symbol HE-SIG₁ 610a can include a content portion 620 (also referred to as content A 620), which can include one or more fields; a CRC1 630; and tail bits 640. In addition, the bits in the symbol HE-SIG₁ 610b can include a content portion 650 (also referred to as content B 650), which can include one or more fields; a CRC2 660; and tail bits 670. Both the tail bits 640 and tail bits 670 can include a specific number of “0” bits (e.g., six “0” bits).

Each of the symbols HE-SIG₁ 610a and HE-SIG₂ 610b can have, for example, the same symbol duration as the IEEE 802.11a L-SIG field 330 such that the false alarm rate can be minimized or otherwise mitigated for communication devices (e.g., receivers) operating according to IEEE 802.11n and/or IEEE 802.11ac. In some embodiments, the symbol duration or the CP duration of HE-SIG₁ 610a and/or HE-SIG₂ 610b may be greater than that of the legacy 802.11a L-SIG filed 330. The constellations of the symbols HE-SIG₁ 610a and HE-SIG₂ 610b can be configured in numerous ways. In one embodiment, the constellations are the same as in IEEE 802.11a with normal BPSK constellation. In another embodiment, the constellations are the same as in IEEE 802.11ac, with one of HE-SIG₁ 610a or HE-SIG₂ 610b modulated according to normal BPSK and the other according to a rotated BPSK (or quadrature BPSK (Q-BPSK)).

In certain embodiments, each of the content A 620 and the content B 650 can include any number of bits in the range from 8 bits to 40 bits, although more or less bits also can be contemplated. In addition or in other embodiments, a portion of the OFDM subcarriers that convey the content A 620 can be utilized to repeat a portion of the symbol(s) in the L-SIG field 330. For instance, signals on even OFDM subcarriers that are included in the content A 620 can replicate the portion of the symbol(s) in the L-SIG field 330. Such repetition can permit increasing the reliability for decoding at least some information, such as the length field in L-SIG field 330. Therefore, some of the content A 620 can be directed to be used in HE-SIG, with exception of those subcarriers that repeat the signals in the symbol(s) of the L-SIG field 330. The communication device (e.g., communication device 110) that transmits the example preamble 600 can encode or otherwise process HE-SIG₁ 610a as described herein, including the described repetition of signals.

As illustrated, a communication device encoding the HE-SIG₁ 610a symbol can include content A 620, CRC1 630, and tail bits 640 (a sequence of six “0” bits, for example). Similarly, the communication device can encode the HE-SIG₂ 610b symbol to include content B 650, CRC2 660, and tail bits 670. Similar to other content described herein, the content A 620 and the content B 650 can include formatting information. It can be appreciated that HE-SIG₁ 610a and HE-SIG₂ 610b symbols can be encoded separately, and that the encoding can be terminated by tail bits (e.g., tail bits 640 and tail bits 670) for each of HE-SIG₁ 610a and HE-SIG₂ 610b symbols. In addition, CRC can be used for each of the HE-SIG₁ 610a and HE-SIG₂ 610b symbols. In certain implementations, similar to others described herein, the CRC1 630 and the CRC2 660 can be masked by different bits (e.g., a first portion and a second portion of BSSID, or other types of masking) In one example scenario, similar to the preamble 500, if a receiver does not validate the CRC1 630 in HE-SIG1 610a, the receiver can terminate the reception of wireless communication earlier than in the embodiment shown in FIG. 7.

While CRC1 630 and CRC2 660 can be encoded, in one aspect, for reusing legacy components in a communication device (either a transmitter or receiver, or both). Therefore, in certain embodiments, one or more of CRC1 630 and CRC2 660 can be short, e.g., the sequence of bits associated with the short CRC can include 4 bits or 6 bits. Yet, in other embodiments, one or more of CRC1 630 and CRC2 660 can be embodied in a long CRC sequence having more than six bits, e.g., 8 bits, 10 bits, or 12 bits. The long CRC can be defined for IEEE 802.11ax protocols.

In addition, the communication device (e.g., a transmitter) that encodes HE-SIG₁ 610a and HE-SIG₂ 610b can utilize or otherwise rely on a normal convolutional code in order to encode HE-SIG₁ 610a and HE-SIG₂ 610b, and in one aspect, the tail bits 640 and the tail bits 670 can be included to terminate the encoder. In other embodiments, the communication device can utilize or otherwise rely on a tail biting convolutional code in order to encode HE-SIG₁ 510a. Accordingly, in such embodiments, one or more of the tail bits 640 or tail bits 670 can be removed from HE-SIG₁ 610a and HE-SIG₂ 610b.

FIG. 7 presents an example of a bit sequence in an example preamble 700 of a packet in accordance with one or more embodiments of the disclosure. Similar to other preambles of the disclosure, the example preamble 700 includes an L-STF 310, and L-LTF 320, and an L-SIG field 330. In addition, the example preamble 700 includes a HE-SIG field (not depicted) including a first symbol HE-SIG₁ 710a and a second symbol HE-SIG₂ 710b. In one example, such symbols can be the first two symbols of the HE-SIG field shown in FIG. 2. Each of the symbols HE-SIG₁ 710a and HE-SIG₂ 710b can have, for example, the same symbol duration as the IEEE 802.11a legacy signal field 330 such that the false alarm rate can be minimized or otherwise mitigated for communication devices (e.g., receivers) operating according to IEEE 802.11n and/or IEEE 802.11ac. In some embodiments, the symbol duration or the CP duration of HE-SIG₁ 710a and/or HE-SIG₂ 710b may be greater than that of the legacy 802.11a L-SIG filed 330. The constellations of the symbols HE-SIG₁ 710a and HE-SIG₂ 710b can be configured in numerous ways. In one embodiment, the constellations are the same as in IEEE 802.11a with normal BPSK constellation. In another embodiment, the constellations are the same as in IEEE 802.11ac, with one of HE-SIG₁ 710a or HE-SIG₂ 710b modulated according to normal BPSK and the other according to a rotated BPSK (or quadrature BPSK (Q-BPSK)).

In certain embodiments, each of the content A 720 and the content B 740 can include any number of bits in the range from 8 bits to 40 bits, although more or less bits also can be contemplated. In addition or in other embodiments, a portion of the OFDM subcarriers that convey the content A 720 can be utilized to repeat a portion of the symbol(s) in the L-SIG field 330. For instance, signals on even OFDM subcarriers that are included in the content A 620 can replicate the portion of the symbol(s) in the L-SIG field 330. Such repetition can permit increasing the reliability for decoding at least some information, such as the length field in L-SIG field 330. Therefore, some of the content A 720 can be directed to be used in HE-SIG, with exception of those subcarriers that repeat the signals in the symbol(s) of the L-SIG field 330. The communication device (e.g., communication device 110) that transmits the example preamble 700 can encode or otherwise process HE-SIG₁ 710a as described herein, including the described repetition of signals.

As illustrated, a communication device that encodes the HE-SIG₁ 710a symbol can include content A 720 and tail bits 730 (a sequence of six “0” bits, for example). Similarly, the communication device can encode the HE-SIG₂ 710b symbol to include content B 740, CRC1 750, CRC2 760, and tail bits 770. The content A 720 and the content B 740 can include formatting information—e.g., channel bandwidth (e.g., 20 MHz, 40 MHz, 80 MHz, or 160 MHz), modulation and encoding, number of symbols in a packet, and the like. It can be appreciated that HE-SIG₁ 710a and HE-SIG₂ 710b symbols can be encoded separately, and that the encoding can be terminated by tail bits (e.g., tail bits 730 and tail bits 770) for each of HE-SIG₁ 710a and HE-SIG₂ 710b symbols. In certain implementations, the tail bits 730 and/or 770 can be punctured.

As illustrated, CRC1 750 and CRC2 760 are encoded or otherwise configured in the HE-SIG₂ 710b symbol. Similar to other embodiments described herein, one or more of the CRC1 750 or the CRC2 760 may be masked.

It should be appreciated that, CRC1 750 and CRC2 760 can be encoded, in one aspect, for reusing legacy components in a communication device (either a transmitter or receiver, or both). It should further be appreciated that, in the embodiment shown in FIG. 7, the HE-SIG₂ 710b is intended to have a strong CRC, or other types of integrity verification. Thus, in one implementation, CRC1 750 and CRC2 760 can be utilized to form a single long CRC sequence, as described herein. The long CRC can be defined for IEEE 802.11ax protocols and can include, for example, 8 bits, 10 bits, or 12 bits.

In addition, the communication device (e.g., a transmitter) that encodes HE-SIG₁ 710a and HE-SIG₂ 710b can utilize or otherwise rely on a normal convolutional code in order to encode HE-SIG₁ 710a and HE-SIG₂ 710b. In one aspect, the tail bits 730 and the tail bits 770 can be included to terminate the encoder. In other embodiments, the communication device can utilize or otherwise rely on a tail biting convolutional code in order to encode HE-SIG₁ 710a and HE-SIG₂ 710b. Accordingly, in such embodiments, one or more of (i) the tail bits 730 or (ii) the tail bits 770 can be removed from HE-SIG₁ 710a and/or HE-SIG₂ 710b.

In the present disclosure, as described herein, tail bits can provide increased reliability of the auto-detection. In addition, more tail bits can provide greater resilience to interference, noise, and the like. Yet, in certain implementations, instead of including tail bits (e.g., tail bits 380) for jointly coded symbols, such as HE-SIG₁ 340a and HE-SIG 340b, or individually coded symbols, such as HE-SIG₁ 510a, the encoder of a communication device can be terminated after two or more HE-SIG symbols, without inclusion of tail bits. Simulation results show that termination after two or more HE-SIG symbols performs better than the example preamble structure 600 shown in FIG. 6, which includes tail bits in each of the encoded HE-SIG symbols 610a and 610b. In embodiments in which less tail bits are utilized, there may be left over subcarriers in the OFDM symbols. In certain embodiments, the left over subcarriers can be utilized for repetition transmission. In one example, part of HE-SIG coded symbols can be transmitted more than once using the left over subcarriers. Simulation results show that the same reliability (e.g., packet error rate (PER) as the L-SIG using example embodiment in FIG. 3) can be achieved.

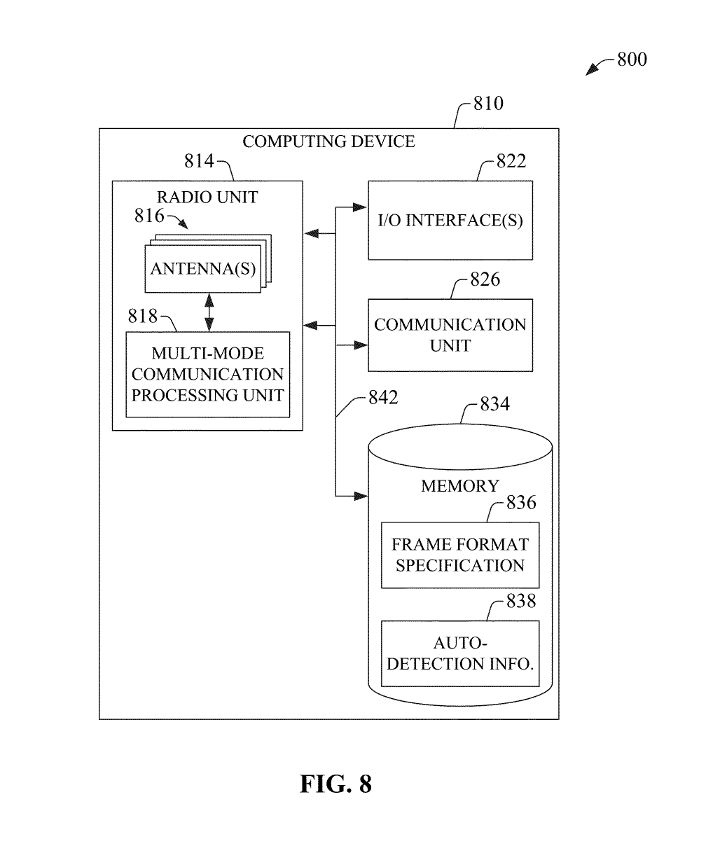

FIG. 8 illustrates a block-diagram of an example embodiment 800 of a computing device 810 that can operate in accordance with at least certain aspects of the disclosure. In one aspect, the computing device 810 can operate as a wireless device and can embody or can comprise an access point, a mobile computing device (e.g., user equipment or station), or other types of communication device that can transmit and/or receive wireless communications in accordance with this disclosure. To permit wireless communication, including the scheduling of resource block allocations as described herein, the computing device 810 includes a radio unit 814 and a communication unit 826. In certain implementations, the communication unit 826 can generate packets or other types of information blocks via a network stack, for example, and can convey the packets or other types of information block to the radio unit 814 for wireless communication. In one embodiment, the network stack (not shown) can be embodied in or can constitute a library or other types of programming module, and the communication unit 826 can execute the network stack in order to generate a packet or other types of information block. Generation of the packet or the information block can include, for example, generation of control information (e.g., checksum data, communication address(es)), traffic information (e.g., payload data), and/or formatting of such information into a specific packet header.

As illustrated, the radio unit 814 can include one or more antennas 816 and a multi-mode communication processing unit 818. In certain embodiments, the antenna(s) 816 can be embodied in or can include directional or omnidirectional antennas, including, for example, dipole antennas, monopole antennas, patch antennas, loop antennas, microstrip antennas or other types of antennas suitable for transmission of RF signals. In addition, or in other embodiments, at least some of the antenna(s) 816 can be physically separated to leverage spatial diversity and related different channel characteristics associated with such diversity. In addition or in other embodiments, the multi-mode communication processing unit 818 that can process at least wireless signals in accordance with one or more radio technology protocols and/or modes (such as MIMO, single-input-multiple-output (SIMO), multiple-input-single-output (MISO), and the like. Each of such protocol(s) can be configured to communicate (e.g., transmit, receive, or exchange) data, metadata, and/or signaling over a specific air interface. The one or more radio technology protocols can include 3GPP UMTS; LTE; LTE-A; Wi-Fi protocols, such as those of the Institute of Electrical and Electronics Engineers (IEEE) 802.11 family of standards; Worldwide Interoperability for Microwave Access (WiMAX); radio technologies and related protocols for ad hoc networks, such as Bluetooth or ZigBee; other protocols for packetized wireless communication; or the like). The multi-mode communication processing unit 818 also can process non-wireless signals (analogic, digital, a combination thereof, or the like).

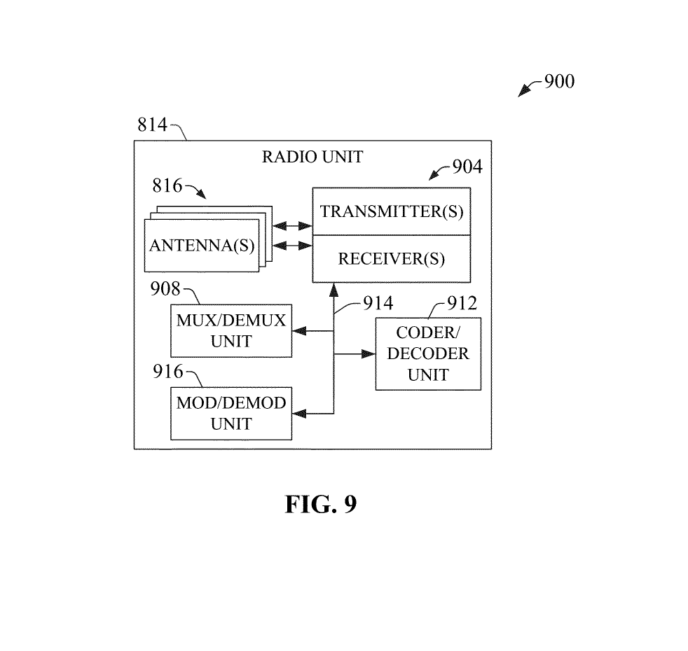

In one embodiment, e.g., example embodiment 900 shown in FIG. 9, the multi-mode communication processing unit 818 can comprise a set of one or more transmitters/receivers 904, and components therein (amplifiers, filters, analog-to-digital (A/D) converters, etc.), functionally coupled to a multiplexer/demultiplexer (mux/demux) unit 908, a modulator/demodulator (mod/demod) unit 916 (also referred to as modem 916), and a coder/decoder unit 912 (also referred to as codec 912). Each of the transmitter(s)/receiver(s) can form respective transceiver(s) that can transmit and receive wireless signal (e.g., electromagnetic radiation) via the one or more antennas 816. It should be appreciated that in other embodiments, the multi-mode communication processing unit 818 can include other functional elements, such as one or more sensors, a sensor hub, an offload engine or unit, a combination thereof, or the like. While illustrated as separate blocks in the computing device 810, it should be appreciated that in certain embodiments, at least a portion of the multi-mode communication processing unit 818 and the communication unit 826 can be integrated into a single unit (e.g., a single chipset or other type of solid state circuitry). In one aspect, such a unit can be configured by programmed instructions retained in the memory 834 and/or other memory devices integrated into or functionally coupled to the unit.

Electronic components and associated circuitry, such as mux/demux unit 908, codec 912, and modem 916 can permit or facilitate processing and manipulation, e.g., coding/decoding, deciphering, and/or modulation/demodulation, of signal(s) received by the computing device 810 and signal(s) to be transmitted by the computing device 810. In one aspect, as described herein, received and transmitted wireless signals can be modulated and/or coded, or otherwise processed, in accordance with one or more radio technology protocols. Such radio technology protocol(s) can include 3GPP UMTS; 3GPP LTE; LTE-A; Wi-Fi protocols, such as IEEE 802.11 family of standards (IEEE 802.ac, IEEE 802.ax, and the like); WiMAX; radio technologies and related protocols for ad hoc networks, such as Bluetooth or ZigBee; other protocols for packetized wireless communication; or the like.

The electronic components in the described communication unit, including the one or more transmitters/receivers 904, can exchange information (e.g., data, metadata, code instructions, signaling and related payload data, combinations thereof, or the like) through a bus 914, which can embody or can comprise at least one of a system bus, an address bus, a data bus, a message bus, a reference link or interface, a combination thereof, or the like. Each of the one or more receivers/transmitters 904 can convert signal from analog to digital and vice versa. In addition or in the alternative, the receiver(s)/transmitter(s) 904 can divide a single data stream into multiple parallel data streams, or perform the reciprocal operation. Such operations may be conducted as part of various multiplexing schemes. As illustrated, the mux/demux unit 908 is functionally coupled to the one or more receivers/transmitters 904 and can permit processing of signals in time and frequency domain. In one aspect, the mux/demux unit 908 can multiplex and demultiplex information (e.g., data, metadata, and/or signaling) according to various multiplexing schemes such as time division multiplexing (TDM), frequency division multiplexing (FDM), orthogonal frequency division multiplexing (OFDM), code division multiplexing (CDM), space division multiplexing (SDM). In addition or in the alternative, in another aspect, the mux/demux unit 908 can scramble and spread information (e.g., codes) according to most any code, such as Hadamard-Walsh codes, Baker codes, Kasami codes, polyphase codes, and the like. The modem 916 can modulate and demodulate information (e.g., data, metadata, signaling, or a combination thereof) according to various modulation techniques, such as frequency modulation (e.g., frequency-shift keying), amplitude modulation (e.g., M-ary quadrature amplitude modulation (QAM), with M a positive integer; amplitude-shift keying (ASK)), phase-shift keying (PSK), and the like). In addition, processor(s) that can be included in the computing device 810 (e.g., processor(s) included in the radio unit 814 or other functional element(s) of the computing device 810) can permit processing data (e.g., symbols, bits, or chips) for multiplexing/demultiplexing, modulation/demodulation (such as implementing direct and inverse fast Fourier transforms) selection of modulation rates, selection of data packet formats, inter-packet times, and the like.

The codec 912 can operate on information (e.g., data, metadata, signaling, or a combination thereof) in accordance with one or more coding/decoding schemes suitable for communication, at least in part, through the one or more transceivers formed from respective transmitter(s)/receiver(s) 904. In one aspect, such coding/decoding schemes, or related procedure(s), can be retained as a group of one or more computer-accessible instructions (computer-readable instructions, computer-executable instructions, or a combination thereof) in one or more memory devices 834 (referred to as memory 834). In a scenario in which wireless communication among the computing device 810 and another computing device (e.g., a station or other types of user equipment) utilizes MIMO, MISO, SIMO, or SISO operation, the codec 912 can implement at least one of space-time block coding (STBC) and associated decoding, or space-frequency block (SFBC) coding and associated decoding. In addition or in the alternative, the codec 912 can extract information from data streams coded in accordance with spatial multiplexing scheme. In one aspect, to decode received information (e.g., data, metadata, signaling, or a combination thereof), the codec 912 can implement at least one of computation of log-likelihood ratios (LLR) associated with constellation realization for a specific demodulation; maximal ratio combining (MRC) filtering, maximum-likelihood (ML) detection, successive interference cancellation (SIC) detection, zero forcing (ZF) and minimum mean square error estimation (MMSE) detection, or the like. The codec 912 can utilize, at least in part, mux/demux unit 908 and mod/demod unit 916 to operate in accordance with aspects described herein.

With further reference to FIG. 8, the computing device 810 can operate in a variety of wireless environments having wireless signals conveyed in different electromagnetic radiation (EM) frequency bands. To at least such end, the multi-mode communication processing unit 818 in accordance with aspects of the disclosure can process (code, decode, format, etc.) wireless signals within a set of one or more EM frequency bands (also referred to as frequency bands) comprising one or more of radio frequency (RF) portions of the EM spectrum, microwave portion(s) of the EM spectrum, or infrared (IR) portion(s) of the EM spectrum. In one aspect, the set of one or more frequency bands can include at least one of (i) all or most licensed EM frequency bands, (such as the industrial, scientific, and medical (ISM) bands, including the 2.4 GHz band or the 5 GHz bands); or (ii) all or most unlicensed frequency bands (such as the 60 GHz band) currently available for telecommunication.

The computing device 810 can receive and/or transmit information encoded and/or modulated or otherwise processed in accordance with aspects of the present disclosure. To at least such an end, in certain embodiments, the computing device 810 can acquire or otherwise access information wirelessly via the radio unit 814 (also referred to as radio 814), where at least a portion of such information can be encoded and/or modulated in accordance with aspects described herein. More specifically, for example, the information can include packets (e.g., PPDUs) in accordance with embodiments of the disclosure, such as those shown in FIGS. 3-7. As illustrated, in certain embodiments, the computing device 810 can include one or more memory elements 836 (referred to frame format specification 836) that can include information defining or otherwise specifying one or more preambles of radio packets for auto-detection in accordance with one or more aspects of this disclosure. In one example, the communication unit 826 can access at least a portion of the information in the frame format specification 836 and can generate (e.g., encode) a packet having a preamble in accordance with one of those described in FIGS. 3-7. In addition, the communication device 810, via the communication unit 826, for example, can determine or otherwise compute CRC bit sequences or other validation bit sequences for auto-detection in accordance with this disclosure and can retain those sequences in one or more memory elements 838 (referred to as auto-detection information 838). The auto-detection information 838 also can include other CRC bit sequences or other type of validation bit sequences for auto-detection in accordance with this disclosure. To that end, in one aspect, the communication unit 624, for example, can compare a computed CRC bit sequence with a reference (or otherwise expected) CRC bit sequence that can be stored in the auto-detection information 838. The auto-detection information 838 also can include information indicative or otherwise representative of masks and/or utilization thereof (e.g., specific manner of masking or unmasking) in accordance with aspects described herein. As described herein, the masks can include specific bit sequences having specific number of bits.

The memory 834 can contain one or more memory elements having information suitable for processing information received according to a predetermined communication protocol (e.g., IEEE 802.11ac or IEEE 802.11ax). While not shown, in certain embodiments, one or more memory elements of the memory 834 can include computer-accessible instructions that can be executed by one or more of the functional elements of the computing device 810 in order to implement at least some of the functionality for auto-detection described herein, including processing of information communicated (e.g., encoded, modulated, and/or arranged) in accordance with aspect of the disclosure. One or more groups of such computer-accessible instructions can embody or can constitute a programming interface that can permit communication of information (e.g., data, metadata, and/or signaling) between functional elements of the computing device 810 for implementation of such functionality.

As illustrated, the computing device 810 can include one or more I/O interfaces 822. At least one of the I/O interface(s) 822 can permit the exchange of information between the computing device 810 and another computing device and/or a storage device. Such an exchange can be wireless (e.g., via near field communication or optically-switched communication) or wireline. At least another one of the I/O interface(s) 822 can permit presenting information visually, aurally, and/or via movement to an end-user of the computing device 610. In one example, a haptic device can embody the I/O interface of the I/O interface(s) 822 that permit conveying information via movement. In addition, in the illustrated computing device 810, a bus architecture 842 (also referred to as bus 842) can permit the exchange of information (e.g., data, metadata, and/or signaling) between two or more functional elements of the computing device 810. For instance, the bus 842 can permit exchange of information between two or more of (i) the radio unit 814 or a functional element therein, (ii) at least one of the I/O interface(s) 822, (iii) the communication unit 826, or (iv) the memory 834. In addition, one or more application programming interfaces (APIs) (not depicted in FIG. 8) or other types of programming interfaces that can permit exchange of information (e.g., data and/or metadata) between two or more of the functional elements of the client device 810. At least one of such API(s) can be retained or otherwise stored in the memory 834. In certain embodiments, it should be appreciated that at least one of the API(s) or other programming interfaces can permit the exchange of information within components of the communication unit 826. The bus 842 also can permit a similar exchange of information. In certain embodiments, the bus 852 can embody or can include at least one of a system bus, an address bus, a data bus, a message bus, a reference link or interface, a combination thereof, or the like. In addition or in other embodiments, the bus 852 can include, for example, components for wireline and wireless communication.

It should be appreciated that portions of the computing device 810 can embody or can constitute an apparatus. For instance, the multi-mode communication processing unit 818, the communication unit 826, and at least a portion of the memory 834 can embody or can constitute an apparatus that can operate in accordance with one or more aspects of this disclosure.

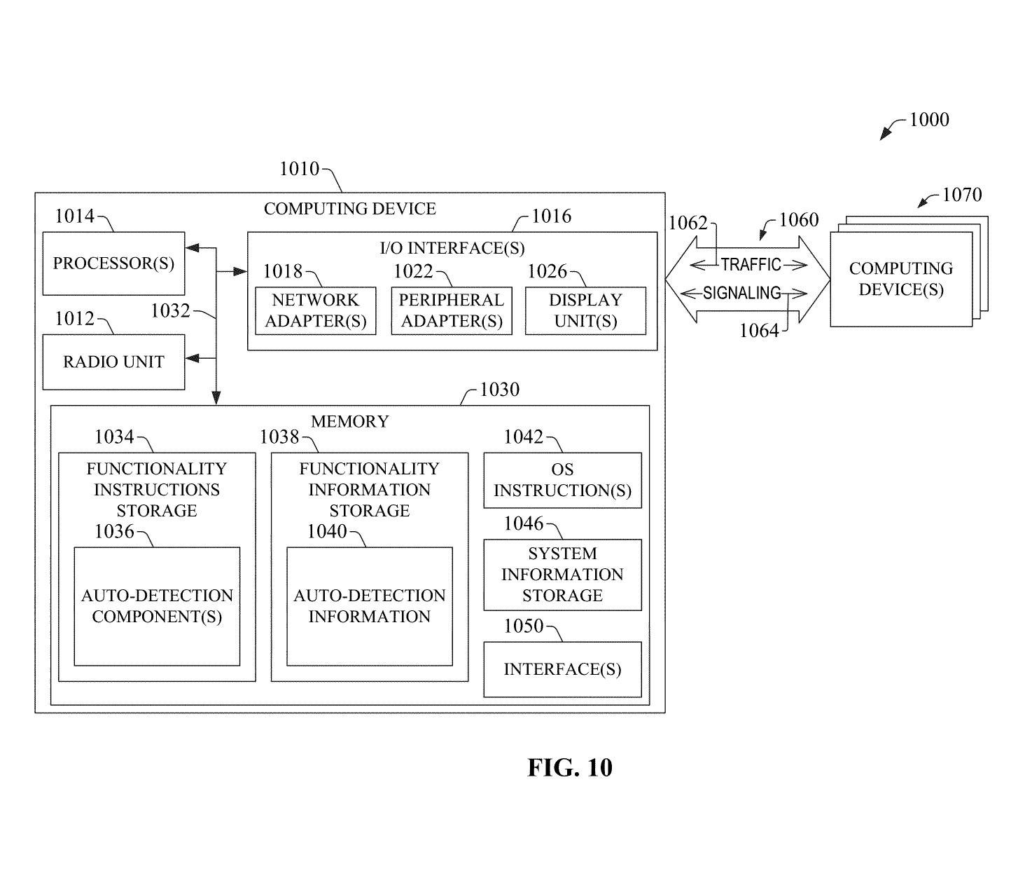

FIG. 10 illustrates an example of a computational environment 1000 for auto-detection in accordance with one or more aspects of the disclosure. The example computational environment 1000 is only illustrative and is not intended to suggest or otherwise convey any limitation as to the scope of use or functionality of such computational environments' architecture. In addition, the computational environment 1000 should not be interpreted as having any dependency or requirement relating to any one or combination of components illustrated in this example computational environment. The illustrative computational environment 1000 can embody or can include, for example, the computing device 110, one or more of the base stations 114a, 114b, or 114c, and/or any other computing device (e.g., computing device 810) that can implement or otherwise leverage the auto-detection features described herein.

The computational environment 1000 represents an example of a software implementation of the various aspects or features of the disclosure in which the processing or execution of operations described in connection with auto-detection described herein, including processing of information communicated (e.g., encoded, modulated, and/or arranged) in accordance with this disclosure, can be performed in response to execution of one or more software components at the computing device 1010. It should be appreciated that the one or more software components can render the computing device 1010, or any other computing device that contains such components, a particular machine for auto-detection described herein, including processing of information encoded, modulated, and/or arranged in accordance with aspects described herein, among other functional purposes. A software component can be embodied in or can comprise one or more computer-accessible instructions, e.g., computer-readable and/or computer-executable instructions. At least a portion of the computer-accessible instructions can embody one or more of the example techniques disclosed herein. For instance, to embody one such method, at least the portion of the computer-accessible instructions can be persisted (e.g., stored, made available, or stored and made available) in a computer storage non-transitory medium and executed by a processor. The one or more computer-accessible (or processor-accessible) instructions that embody a software component can be assembled into one or more program modules, for example, that can be compiled, linked, and/or executed at the computing device 1010 or other computing devices. Generally, such program modules comprise computer code, routines, programs, objects, components, information structures (e.g., data structures and/or metadata structures), etc., that can perform particular tasks (e.g., one or more operations) in response to execution by one or more processors, which can be integrated into the computing device 1010 or functionally coupled thereto.

The various example embodiments of the disclosure can be operational with numerous other general purpose or special purpose computing system environments or configurations. Examples of well-known computing systems, environments, and/or configurations that can be suitable for implementation of various aspects or features of the disclosure in connection with auto-detection, including processing of information communicated (e.g., encoded, modulated, and/or arranged) in accordance with features described herein, can comprise personal computers; server computers; laptop devices; handheld computing devices, such as mobile tablets; wearable computing devices; and multiprocessor systems. Additional examples can include set top boxes, programmable consumer electronics, network PCs, minicomputers, mainframe computers, blade computers, programmable logic controllers, distributed computing environments that comprise any of the above systems or devices, and the like.

As illustrated, the computing device 1010 can comprise one or more processors 1014, one or more input/output (I/O) interfaces 1016, a memory 1030, and a bus architecture 1032 (also termed bus 1032) that functionally couples various functional elements of the computing device 1010. As illustrated, the computing device 1010 also can include a radio unit 1012. In one example, similarly to the radio unit 814, the radio unit 1012 can include one or more antennas and a communication processing unit that can permit wireless communication between the computing device 1010 and another device, such as one of the computing device(s) 1070. The bus 1032 can include at least one of a system bus, a memory bus, an address bus, or a message bus, and can permit exchange of information (data, metadata, and/or signaling) between the processor(s) 1014, the I/O interface(s) 1016, and/or the memory 1030, or respective functional element therein. In certain scenarios, the bus 1032 in conjunction with one or more internal programming interfaces 1050 (also referred to as interface(s) 1050) can permit such exchange of information. In scenarios in which processor(s) 1014 include multiple processors, the computing device 1010 can utilize parallel computing.

The I/O interface(s) 1016 can permit or otherwise facilitate communication of information between the computing device and an external device, such as another computing device, e.g., a network element or an end-user device. Such communication can include direct communication or indirect communication, such as exchange of information between the computing device 1010 and the external device via a network or elements thereof. As illustrated, the I/O interface(s) 1016 can comprise one or more of network adapter(s) 1018, peripheral adapter(s) 1022, and display unit(s) 1026. Such adapter(s) can permit or facilitate connectivity between the external device and one or more of the processor(s) 1014 or the memory 1030. In one aspect, at least one of the network adapter(s) 1018 can couple functionally the computing device 1010 to one or more computing devices 1070 via one or more traffic and signaling pipes 1060 that can permit or facilitate exchange of traffic 1062 and signaling 1064 between the computing device 1010 and the one or more computing devices 1070. Such network coupling provided at least in part by the at least one of the network adapter(s) 1018 can be implemented in a wired environment, a wireless environment, or both. Therefore, it should be appreciated that in certain embodiments, the functionality of the radio unit 1012 can be provided by a combination of at least one of the network adapter(s) 1018 and at least one of the processor(s) 1014. Accordingly, in such embodiments, the radio unit 1012 may not be included in the computing device 1010. The information that is communicated by the at least one network adapter can result from implementation of one or more operations in a method of the disclosure. Such output can be any form of visual representation, including, but not limited to, textual, graphical, animation, audio, tactile, and the like. In certain scenarios, each of the computing device(s) 1070 can have substantially the same architecture as the computing device 1010. In addition or in the alternative, the display unit(s) 1026 can include functional elements (e.g., lights, such as light-emitting diodes; a display, such as liquid crystal display (LCD), combinations thereof, or the like) that can permit control of the operation of the computing device 1010, or can permit conveying or revealing operational conditions of the computing device 1010.

In one aspect, the bus 1032 represents one or more of several possible types of bus structures, including a memory bus or memory controller, a peripheral bus, an accelerated graphics port, and a processor or local bus using any of a variety of bus architectures. As an illustration, such architectures can comprise an Industry Standard Architecture (ISA) bus, a Micro Channel Architecture (MCA) bus, an Enhanced ISA (EISA) bus, a Video Electronics Standards Association (VESA) local bus, an Accelerated Graphics Port (AGP) bus, and a Peripheral Component Interconnects (PCI) bus, a PCI-Express bus, a Personal Computer Memory Card Industry Association (PCMCIA) bus, Universal Serial Bus (USB), and the like. The bus 1032, and all buses described herein can be implemented over a wired or wireless network connection and each of the subsystems, including the processor(s) 1014, the memory 1030 and memory elements therein, and the I/O interface(s) 1016 can be contained within one or more remote computing devices 1070 at physically separate locations, connected through buses of this form, in effect implementing a fully distributed system.

The computing device 1010 can comprise a variety of computer-readable media. Computer readable media can be any available media (transitory and non-transitory) that can be accessed by a computing device. In one aspect, computer-readable media can comprise computer non-transitory storage media (or computer-readable non-transitory storage media) and communications media. Example computer-readable non-transitory storage media can be any available media that can be accessed by the computing device 1010, and can comprise, for example, both volatile and non-volatile media, and removable and/or non-removable media. In one aspect, the memory 1030 can comprise computer-readable media in the form of volatile memory, such as random access memory (RAM), and/or non-volatile memory, such as read only memory (ROM).

The memory 1030 can comprise functionality instructions storage 1034 and functionality information storage 1038. The functionality instructions storage 1034 can comprise computer-accessible instructions that, in response to execution (by at least one of the processor(s) 1014), can implement one or more of the functionalities of the disclosure. The computer-accessible instructions can embody or can comprise one or more software components illustrated as auto-detection component(s) 1036. In one scenario, execution of at least one component of the auto-detection component(s) 1036 can implement one or more of the techniques disclosed herein. For instance, such execution can cause a processor that executes the at least one component to carry out a disclosed example method. It should be appreciated that, in one aspect, a processor of the processor(s) 1014 that executes at least one of the auto-detection component(s) 1036 can retrieve information from or retain information in a memory element 1040 in the functionality information storage 1038 in order to operate in accordance with the functionality programmed or otherwise configured by the auto-detection component(s) 1036. Such information can include at least one of code instructions, information structures, or the like. At least one of the one or more interfaces 1050 (e.g., application programming interface(s)) can permit or facilitate communication of information between two or more components within the functionality instructions storage 1034. The information that is communicated by the at least one interface can result from implementation of one or more operations in a method of the disclosure. In certain embodiments, one or more of the functionality instructions storage 1034 and the functionality information storage 1038 can be embodied in or can comprise removable/non-removable, and/or volatile/non-volatile computer storage media.

At least a portion of at least one of the auto-detection component(s) 1036 or auto-detection information 1040 can program or otherwise configure one or more of the processors 1014 to operate at least in accordance with the functionality described herein. One or more of the processor(s) 1014 can execute at least one of such components and leverage at least a portion of the information in the storage 1038 in order to provide auto-detection in accordance with one or more aspects described herein. More specifically, yet not exclusively, execution of one or more of the component(s) 1036 can permit transmitting and/or receiving information at the computing device 1010, where the at least a portion of the information include one or more packets having preambles as described in connection with FIGS. 3-7, for example. As such, it should be appreciated that in certain embodiments, a combination of the processor(s) 1014, the auto-detection component(s) 1036, and the auto-detection information 1040 can form means for providing specific functionality for auto-detection of a radio technology protocol version in accordance with one or more aspects of the disclosure.

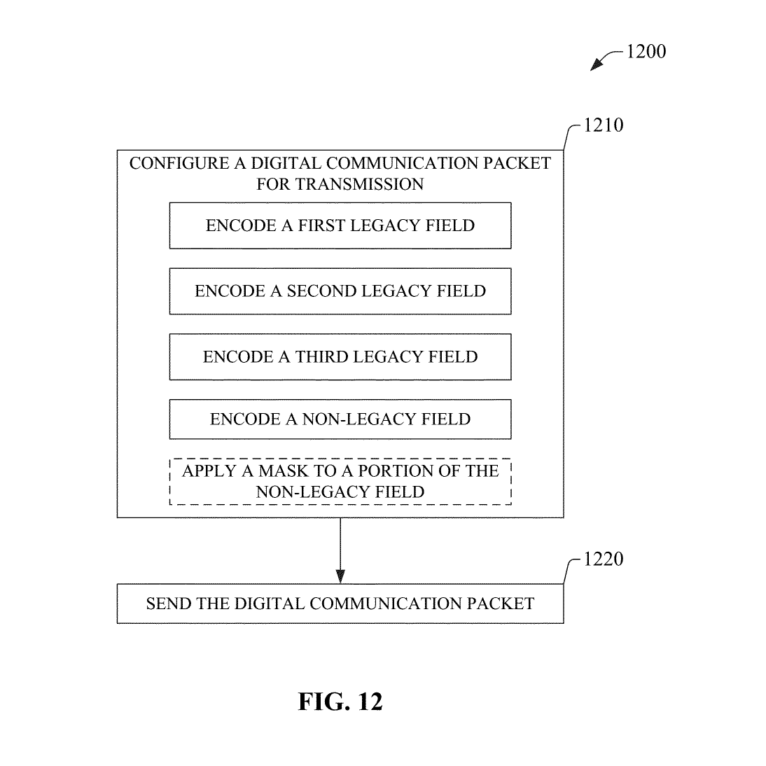

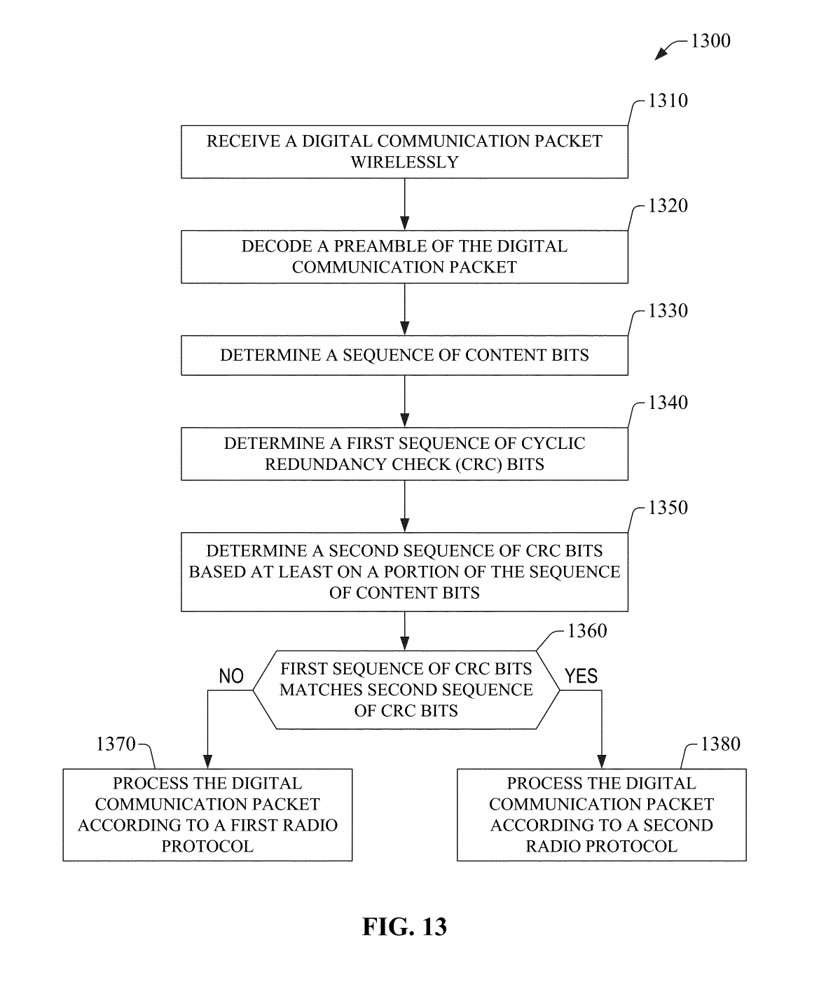

It should be appreciated that, in certain scenarios, the functionality instruction(s) storage 1034 can embody or can comprise a computer-readable non-transitory storage medium having computer-accessible instructions that, in response to execution, cause at least one processor (e.g., one or more of processor(s) 1014) to perform a group of operations comprising the operations or blocks described in connection with the disclosed methods, such as the example methods 1200 and 1300 presented, respectively, in FIG. 12 and FIG. 13.

In addition, the memory 1030 can comprise computer-accessible instructions and information (e.g., data and/or metadata) that permit or facilitate operation and/or administration (e.g., upgrades, software installation, any other configuration, or the like) of the computing device 1010. Accordingly, as illustrated, the memory 1030 can comprise a memory element 1042 (labeled OS instruction(s) 1042) that contains one or more program modules that embody or include one or more OSs, such as Windows operating system, Unix, Linux, Symbian, Android, Chromium, and substantially any OS suitable for mobile computing devices or tethered computing devices. In one aspect, the operational and/or architecture complexity of the computing device 1010 can dictate a suitable OS. The memory 1030 also comprises a system information storage 1046 having data and/or metadata that permits or facilitate operation and/or administration of the computing device 1010. Elements of the OS instruction(s) 1042 and the system information storage 1046 can be accessible or can be operated on by at least one of the processor(s) 1014.

It should be recognized that while the functionality instructions storage 1034 and other executable program components, such as the operating system instruction(s) 1042, are illustrated herein as discrete blocks, such software components can reside at various times in different memory components of the computing device 1010, and can be executed by at least one of the processor(s) 1014. In certain scenarios, an implementation of the auto-detection component(s) 1036 can be retained on or transmitted across some form of computer readable media.

The computing device 1010 and/or one of the computing device(s) 1070 can include a power supply (not shown), which can power up components or functional elements within such devices. The power supply can be a rechargeable power supply, e.g., a rechargeable battery, and it can include one or more transformers to achieve a power level suitable for operation of the computing device 1010 and/or one of the computing device(s) 1070, and components, functional elements, and related circuitry therein. In certain scenarios, the power supply can be attached to a conventional power grid to recharge and ensure that such devices can be operational. In one aspect, the power supply can include an I/O interface (e.g., one of the network adapter(s) 1018) to connect operationally to the conventional power grid. In another aspect, the power supply can include an energy conversion component, such as a solar panel, to provide additional or alternative power resources or autonomy for the computing device 1010 and/or one of the computing device(s) 1070.

The computing device 1010 can operate in a networked environment by utilizing connections to one or more remote computing devices 1070. As an illustration, a remote computing device can be a personal computer, a portable computer, a server, a router, a network computer, a peer device or other common network node, and so on. As described herein, connections (physical and/or logical) between the computing device 1010 and a computing device of the one or more remote computing devices 1070 can be made via one or more traffic and signaling pipes 1060, which can comprise wireline link(s) and/or wireless link(s) and several network elements (such as routers or switches, concentrators, servers, and the like) that form a PAN, a LAN, a WAN, a WPAN, a WLAN, and/or a WWAN. Such networking environments are conventional and commonplace in dwellings, offices, enterprise-wide computer networks, intranets, local area networks, and wide area networks.

It should be appreciated that portions of the computing device 1010 can embody or can constitute an apparatus. For instance, at least one of the processor(s) 1014; at least a portion of the memory 1030, including a portion of auto-detection component(s) 1036 and a portion of the auto-detection information 1040; and at least a portion of the bus 1032 can embody or can constitute an apparatus that can operate in accordance with one or more aspects of this disclosure.

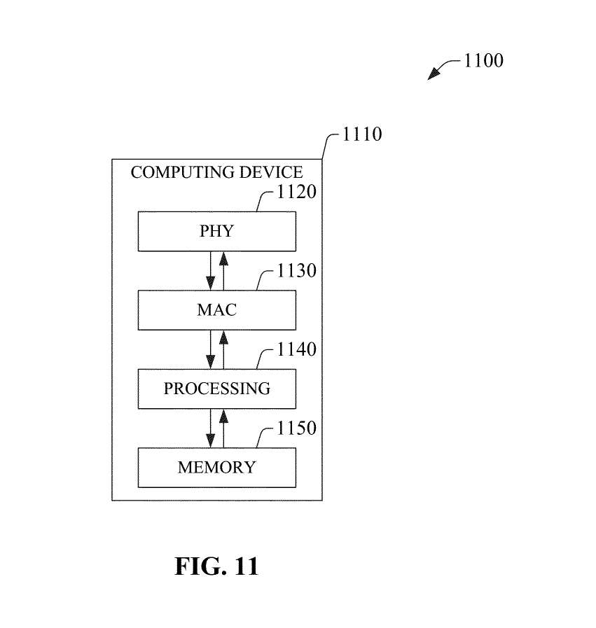

FIG. 11 presents another example embodiment 1100 of a computing device 1110 in accordance with one or more embodiments of the disclosure. The computing device 1110 can embody or can include, for example, the computing device 110, one or more of the base stations 114a, 114b, or 114c, and/or any other computing device (e.g., computing device 810) that implements or otherwise leverages the auto-detection features described herein. In certain embodiments, the computing device 1110 can be a HEW-compliant device that may be configured to communicate with one or more other HEW devices and/or other types of communication devices, such as legacy communication devices. HEW devices and legacy devices also may be referred to as HEW stations (HEW STAs) and legacy STAs, respectively. In one implementation, the computing device 1110 can operate as an access point (such as AP 114a, 114b, or 114c). As illustrated, the computing device 1110 can include, among other things, physical layer (PHY) circuitry 1120 and medium-access-control layer (MAC) circuitry 1130. In one aspect, the PHY circuitry 1110 and the MAC circuitry 1130 can be HEW compliant layers and also can be compliant with one or more legacy IEEE 802.11 standards. In one aspect, the MAC circuitry 1130 can be arranged to configure physical layer converge protocol (PLCP) protocol data units (PPDUs) and arranged to transmit and receive PPDUs, among other things. In addition or in other embodiments, the computing device 1110 also can include other hardware processing circuitry 1140 (e.g., one or more processors) and one or more memory devices 1150 configured to perform the various operations described herein.

In certain embodiments, the MAC circuitry 1130 can be arranged to contend for a wireless medium during a contention period to receive control of the medium for the HEW control period and configure an HEW PPDU. In addition or in other embodiments, the PHY circuitry 1120 can be arranged to transmit the HEW PPDU. The PHY circuitry 1120 can include circuitry for modulation/demodulation, upconversion/downconversion, filtering, amplification, etc. As such, the computing device 1110 can include a transceiver to transmit and receive data such as HEW PPDU. In certain embodiments, the hardware processing circuitry 1140 can include one or more processors. The hardware processing circuitry 1140 can be configured to perform functions based on instructions being stored in a memory device (e.g., RAM or ROM) or based on special purpose circuitry. In certain embodiments, the hardware processing circuitry 1140 can be configured to perform one or more of the functions described herein, such as allocating bandwidth or receiving allocations of bandwidth.

In certain embodiments, one or more antennas may be coupled to or included in the PHY circuitry 1120. The antenna(s) can transmit and receive wireless signals, including transmission of HEW packets or other type of radio packets. As described herein, the one or more antennas can include one or more directional or omnidirectional antennas, including dipole antennas, monopole antennas, patch antennas, loop antennas, microstrip antennas or other types of antennas suitable for transmission of RF signals. In scenarios in which MIMO communication is utilized, the antennas may be physically separated to leverage spatial diversity and the different channel characteristics that may result.

The memory 1150 can retain or otherwise store information for configuring the other circuitry to perform operations for configuring and transmitting HEW packets or other types of radio packets, and performing the various operations described herein including, for example, the encoding and/or decoding of such packets for auto-detection of a radio technology protocol version in accordance with one or more embodiments of this disclosure.

The computing device 1110 can be configured to communicate using OFDM communication signals over a multicarrier communication channel. More specifically, in certain embodiments, the computing device 1110 can be configured to communicate in accordance with one or more specific radio technology protocols, such as the IEEE family of standards including IEEE 802.11, IEEE 802.11n, IEEE 802.11ac, IEEE 802.11ax, DensiFi, and/or proposed specifications for WLANs. In one of such embodiments, the computing device 1110 can utilize or otherwise rely on symbols having a duration that is four times the symbol duration of IEEE 802.11n and/or IEEE 802.11ac. It should be appreciated that the disclosure is not limited in this respect and, in certain embodiments, the computing device 1110 also can transmit and/or receive wireless communications in accordance with other protocols and/or standards.

The computing device 1110 can be embodied in or can constitute a portable wireless communication device, such as a personal digital assistant (PDA), a laptop or portable computer with wireless communication capability, a web tablet, a wireless telephone, a smartphone, a wireless headset, a pager, an instant messaging device, a digital camera, an access point, a television, a medical device (e.g., a heart rate monitor, a blood pressure monitor, etc.), an access point, a base station, a transmit/receive device for a wireless standard such as IEEE 802.11 or IEEE 802.16, or other types of communication device that may receive and/or transmit information wirelessly. Similarly to the computing device 1010, the computing device 1110 can include, for example, one or more of a keyboard, a display, a non-volatile memory port, multiple antennas, a graphics processor, an application processor, speakers, and other mobile device elements. The display may be an LCD screen including a touch screen.

It should be appreciated that while the computing device 1110 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In certain embodiments, the functional elements may refer to one or more processes operating or otherwise executing on one or more processors. It should further be appreciated that portions of the computing device 1110 can embody or can constitute an apparatus. For instance, the processing circuitry 1140 and the memory 1150 can embody or can constitute an apparatus that can operate in accordance with one or more aspects of this disclosure. The apparatus also can include functional elements (e.g., a bus architecture and/or API(s) as described herein) that can permit exchange of information between the processing circuitry 1140 and the memory 1150.

In view of the aspects described herein, various techniques for auto-detection in telecommunications contemplating communication devices that can operate according to different communication protocols can be implemented in accordance with the disclosure. Examples of such techniques can be better appreciated with reference, for example, to the flowcharts in FIGS. 12-13. For purposes of simplicity of explanation, the example method disclosed herein is presented and described as a series of blocks (with each block representing an action or an operation in a method, for example). However, it is to be understood and appreciated that the disclosed method is not limited by the order of blocks and associated actions or operations, as some blocks may occur in different orders and/or concurrently with other blocks from those that are shown and described herein. For example, the various methods (or processes or techniques) in accordance with this disclosure can be alternatively represented as a series of interrelated states or events, such as in a state diagram. Furthermore, not all illustrated blocks, and associated action(s), may be required to implement a method in accordance with one or more aspects of the disclosure. Further yet, two or more of the disclosed methods or processes can be implemented in combination with each other, to accomplish one or more features or advantages described herein.

It should be appreciated that the techniques of the disclosure can be retained on an article of manufacture, or computer-readable medium, to permit or facilitate transporting and transferring such methods to a computing device (e.g., a desktop computer; a mobile computer, such as a tablet, or a smartphone; a gaming console, a mobile telephone; a blade computer; a programmable logic controller, and the like) for execution, and thus implementation, by a processor of the computing device or for storage in a memory thereof or functionally coupled thereto. In one aspect, one or more processors, such as processor(s) that implement (e.g., execute) one or more of the disclosed techniques, can be employed to execute code instructions retained in a memory, or any computer- or machine-readable medium, to implement the one or more methods. The code instructions can provide a computer-executable or machine-executable framework to implement the techniques described herein.

FIG. 12 presents a flowchart of an example method 1200 for wireless communication in accordance with one or more embodiments of the present disclosure. A communication device (e.g., a station or an access point) in accordance with aspects of the disclosure can implement (e.g., execute) the subject example method in its entirety or in part. For example, the computing device 810, the computing device 1010, or the computing device 1110 can implement one or more blocks of the subject example method. It should be appreciated that, in one aspect, the communication device can operate as a transmitter device (or a transmitter) when implementing the subject example method. As an illustration, any one of the communication devices 810, 1010, or 1110 can implement the subject example method. At block 1210, the communication device can configure or otherwise process a digital communication packet for transmission. Such a packet can be embodied in or can include a PPDU and a component of the communication device—e.g., the communication unit 826 or the processing circuitry 1140—can generate the packet. Another component of the communication device (e.g., the multi-mode communication processing unit 818) can configure or otherwise process the digital communication packet for transmission. As illustrated, configuring the digital communication packet for transmission can include encoding, by the communication device, a first legacy field. In addition, configuring the digital communication packet for transmission can include encoding a third legacy field. Further, configuring the digital communication packet for transmission can include encoding a non-legacy field, such as the HE-SIG field 240 shown in FIG. 2. The first legacy field, the second legacy field, and the third legacy field can be embodied in, respectively, the L-STF, the L-LTF, and the L-SIG defined in the family of IEEE 802.11 protocols.

In certain embodiments, as described herein, the communication device can apply a mask to a portion of the non-legacy field. The mask can be embodied in or can include a predetermined sequence of bits (e.g., 10 bits, 11 bits, 12 bits, 13 bits, or 14 bits). In one example, the mask can correspond to 14 bits representing a BSSID. In other examples, the mask can correspond to 10 bits representing a cell ID or a group ID. It should be appreciated that a component of the communication device (e.g., the communication unit 826) can apply the mask by performing an XOR operation between the mask and the portion of the non-legacy field (e.g., a CRC, such as CRC1 360 and/or CRC2 370).

At block 1220, the communication device can send or otherwise provide the digital communication packet wirelessly. To that end, in certain embodiments, a transmitter in a radio unit of the communication device can send the digital communication packet in the air interface. The digital communication packet can be transmitted according to a specific radio technology protocol (legacy or otherwise).

While illustrated with reference to a communication device, it should be appreciated that the subject example method 1200 also can be implemented by other types of apparatuses in accordance with one or more aspects of the present disclosure. For example, one of such apparatuses can include at least one memory device having programmed instructions encoded thereon and at least one processor functionally coupled to the at least one memory and configured to execute the programmed instructions, where in response to execution of the programmed instructions, the at least one processor can perform one or more blocks of the subject example method 1200.

FIG. 13 presents a flowchart of an example method 1300 for wireless communication in accordance with one or more embodiments of the present disclosure. A communication device (e.g., a station or an access point) in accordance with aspects of the disclosure can implement (e.g., execute) the subject example method in its entirety or in part. For example, the computing device 810, the computing device 1010, or the computing device 1110 can implement one or more blocks of the subject example method. It should be appreciated that, in one aspect, the communication device can operate as a receiver device (or receiver) when implementing the subject example method. As an illustration, any one of the communication devices 810, 1010, or 1110 can implement the subject example method. At block 1310, the communication device can receive a digital communication packet wirelessly. As described herein, the digital communication packet can include a preamble and, at block 1320, the communication device can decode the preamble of the digital communication packet. At block 1330, the communication device can determine a sequence of bits associated with content based at least on the decoding of the preamble at block 1320. Such a sequence can be referred to as a sequence of content bits, and the content can include formatting information associated with the received packet, as described herein. At block 1340, a first sequence of bits for CRC or other types of validation check can be determined based at least on the decoding of the preamble at block 1320. Such a first sequence can be referred to as a first sequence of CRC bits. As described herein in connection with FIGS. 3-7, for example, the first sequence of CRC bits can include six bits, eight bits, 10 bits, 12 bits, or any other number of bits. At block 1350, the communication device can determine a second sequence of CRC bits. In certain implementations, the communication device can be configured with a specific procedure or process to compute a sequence of CRC bits from a received sequence of content bits.

At block 1360, the communication device can determine if the first sequence of CRC bits match the second sequence of CRC bits. To that end, the communication device can compare (bit by bit, for example) the first sequence of CRC bits with the second sequence of CRC bits. In response to ascertaining that the first and second CRC sequences do not match or are otherwise a mismatch (the “NO” branch), the communication device can process the digital communication packet according to a first radio protocol (e.g., a legacy Wi-Fi protocol, such as IEEE 802.11ac) at block 1370. In the alternative, in response to ascertaining that the first and second sequences match (the “YES” branch), the communication device can process the digital communication packet according to a second radio protocol (e.g., a new generation Wi-Fi protocol, such as IEEE 802.11ax) at block 1380.

It can be appreciated that implementation of the example method 1300 at a receiver device can permit auto-detection of the radio protocol of a wirelessly received packet. More specifically, yet not exclusively, the comparison of a decoded sequence of CRC bits and another sequence of CRC bits computed from received content can indicate the radio protocol of the wirelessly received packet. While illustrated with reference to a communication device, it should be appreciated that the subject example method 1300 also can be implemented by other types of apparatuses in accordance with one or more aspects of the present disclosure. For example, one of such apparatuses can include at least one memory device having programmed instructions encoded thereon and at least one processor functionally coupled to the at least one memory and configured to execute the programmed instructions, where in response to execution of the programmed instructions, the at least one processor can perform one or more blocks of the subject example method 1300.

Additional or alternative embodiments of the disclosure readily emerge from the description herein and the annexed drawings. In certain embodiments, the disclosure provides an apparatus for wireless telecommunication. The apparatus can include at least one radio unit; at least one memory device having programmed instructions; and at least one processor functionally coupled to the at least one memory device and configured to execute the programmed instructions. In response to execution of the programmed instructions, the processor can be further configured at least to: encode a first legacy field of a digital communication packet; encode a second legacy field of the digital communication packet, encode a third legacy field of the digital communication packet, and encode a non-legacy field of the digital communication packet, the non-legacy field having at least two symbols and including a sequence of content bits and a sequence of cyclic redundancy check (CRC) bits; and send the digital communication packet wirelessly.

In addition or in other embodiment of the apparatus, the at least processor can be further configured to jointly encode two symbols of the at least two symbols, the jointly encoded two symbols including the sequence of content bits, the sequence of CRC bits, and a sequence of tail bits.

In addition or in other embodiments of the apparatus, the at least processor can be further configured to jointly encode two symbols of the at least two symbols, the jointly encoded two symbols including a first sequence of content bits, a first sequence of CRC bits, a second sequence of content bits, a second sequence of CRC bits, and a sequence of tail bits.

In addition or in other embodiments of the apparatus, the at least processor can be further configured to encode individually a first symbol of the at least one of the two symbols, the individually encoded first symbol including a first sequence of content bits, a first sequence of CRC bits, a second sequence for CRC bits, and a sequence of tail bits.

In addition or in other embodiments of the apparatus, the sequence of CRC bits can include 12 bits. Further or in yet other embodiments of the apparatus, the sequence of CRC bits can include six bits. Further or in still other embodiments of the apparatus, the sequence of CRC bits can include eight bits.

In certain embodiments, the disclosure can provide an apparatus for wireless telecommunication. The apparatus can include at least one radio unit; at least one memory device having programmed instructions; and at least one processor functionally coupled to the at least one memory device and configured to execute the programmed instructions. In response to execution of the programmed instructions, the at least one processor can be further configured to: decode a preamble of a digital communication packet, the preamble comprising a field having at least two symbols; determine a sequence of content bits based at least on the decoded preamble; determine a first sequence of cyclic redundancy check (CRC) bits based at least on the decoded field; determine a second sequence of CRC bits based at least on a portion of the sequence of content bits; compare the first sequence of CRC bits and the second sequence of CRC bits; determine that the first sequence of CRC bits and the second sequence of CRC bits match; and process the at least one packet in accordance with a predetermined radio technology protocol.

In addition or in other embodiments of such an apparatus, the at least one processor can be further configured to determine that the first sequence of CRC bits and the second sequence of CRC bits are a mismatch; and to process the digital communication packet according to a second predetermined radio technology protocol.

In addition or in other embodiments of such an apparatus, the at least one processor can be further configured to determine a sequence of 12 CRC bits, a sequence of 10 CRC bits, a sequence of eight CRC bits, or a sequence of six CRC bits.

In addition or in other embodiments of such an apparatus, the at least one processor can be further configured to determine the first sequence of CRC bits from two jointly encoded symbols of the at least two symbols.

In addition or in other embodiments of such an apparatus, the at least one processor can be further configured to determine the first sequence of CRC bits from a singly encoded symbol of the at least two symbols.

In addition or in other embodiments of such an apparatus, the at least one processor can be further configured to determine a mask for the first sequence of CRC bits.

In certain embodiments, the disclosure also provides a method for wireless communication. The method for wireless communication can include: decoding, by a computing device comprising one or more processors coupled to one or more memory devices, a preamble of a digital communication packet the decoding comprising decoding a field having at least two symbols; determining, by the computing device, a sequence of content bits based at least on decoding the field; determining, by the computing device, a first sequence of cyclic redundancy check (CRC) bits based at least on decoding the field; determining, by the computing device, a second sequence of CRC bits based at least on a portion of the sequence of content bits; comparing, by the computing device, the first sequence of CRC bits and the second sequence of CRC bits; determining, by the computing device, that the first sequence of CRC bits and the second sequence of CRC bits match; and processing, by the computing device, the digital communication packet according to a predetermined radio technology protocol.

In addition or in other embodiments, the method can further include determining, by the computing device, that the first sequence of CRC bits and the second sequence of CRC bits are a mismatch; and processing, by the computing device, the digital communication packet according to a second predetermined radio technology protocol.

In addition or in other embodiments of the method, determining the first sequence of CRC bits comprises determining, by the computing device, a sequence of 12 bits, a sequence of 10 bits, a sequence of eight bits, or a sequence of six bits.

In addition or in other embodiments of the method, determining the first sequence of CRC bits can include determining, by the computing device, two sequences of CRC bits received after the sequence of content bits is received.

In addition or in other embodiments of the method, determining the first sequence of CRC bits can include determining, by the computing device, the first sequence of CRC bits from two jointly encoded symbols of the at least two symbols.

In addition or in other embodiments of the method, determining the first sequence of CRC bits can include determining, by the computing device, the first sequence of CRC bits from a singly encoded symbol of the at least two symbols.

In addition or in other embodiments, the method can further include unmasking, by the computing device, a fourth sequence of bits obtained from decoding the field prior to determining the second sequence of bits.

In certain embodiments, the disclosure provides another method for wireless communication. The method can include: encoding, by a computing device comprising one or more processors coupled to one or more memory devices, a digital communication packet, the encoding comprising encoding, by the computing device, a first legacy field, encoding, by the computing device, a second legacy field, encoding, by the computing device, a third legacy field, and encoding, by the computing device, a non-legacy field having at least two symbols, the non-legacy field including a sequence of content bits and a sequence of cyclic redundancy check (CRC) bits; and transmitting, by the computing device, the digital communication packet wirelessly.

In addition or in other embodiments of such a method, encoding the non-legacy field can include jointly encoding, by the computing device, two symbols of the at least two symbols, the jointly encoded two symbols including the sequence of content bits, the sequence of CRC bits, and a sequence of tail bits.

In addition or in other embodiments of such a method, encoding the non-legacy field can include jointly encoding, by the computing device, two symbols of the at least two symbols, the jointly encoded two symbols including a first sequence of content bits, a first sequence of CRC bits, a second sequence of content bits, a second sequence of CRC bits, and a sequence of tail bits.

In addition or in other embodiments of such a method, encoding the non-legacy field can include individually encoding, by the computing device, a first symbol of the at least one of the two symbols, the individually encoded first symbol including a first sequence of content bits, a first sequence of CRC bits, a second sequence for CRC bits, and a sequence of tail bits.

In certain embodiments, the disclosure can provide at least one computer-readable non-transitory storage medium having encoded thereon instructions that, in response to execution, cause an apparatus (e.g., a processor, a chipset having processor(s) and memory(ies), or the like) to perform operations including: decoding a preamble of a digital communication packet the decoding comprising decoding a field having at least two symbols; determining a sequence of content bits based at least on decoding the field; determining a first sequence of cyclic redundancy check (CRC) bits based at least on decoding the field; determining a second sequence of CRC bits based at least on a portion of the sequence of content bits; comparing the first sequence of CRC bits and the second sequence of CRC bits; determining that the first sequence of CRC bits and the second sequence of CRC bits match; and processing the digital communication packet according to a predetermined radio technology protocol.

In addition or in other embodiments of the at least one computer-readable non-transitory storage medium, the operations can further include determining that the first sequence of CRC bits and the second sequence of CRC bits are a mismatch; and processing the digital communication packet according to a second predetermined radio technology protocol.

In addition or in other embodiments of the at least one computer-readable non-transitory storage medium, determining the first sequence of CRC bits can include determining a sequence of 12 bits, a sequence of 10 bits, a sequence of eight bits, or a sequence of six bits.

In addition or in other embodiments of the at least one computer-readable non-transitory storage medium, determining the first sequence of CRC bits comprises determining two sequences of CRC bits received after the sequence of content bits is received.

In addition or in other embodiments of the at least one computer-readable non-transitory storage medium, determining the first sequence of CRC bits can include determining the first sequence of CRC bits from two jointly encoded symbols of the at least two symbols.

In addition or in other embodiments of the at least one computer-readable non-transitory storage medium, determining the first sequence of CRC bits comprises determining the first sequence of CRC bits from a singly encoded symbol of the at least two symbols.

In addition or in other embodiments of the at least one computer-readable non-transitory storage medium, the operations can further include unmasking a fourth sequence of bits obtained from decoding the field prior to determining the second sequence of bits.

In certain embodiments, the disclosure can provide at least one computer-readable non-transitory storage medium having encoded thereon instructions that, in response to execution, cause an apparatus to perform operations including: encoding a digital communication packet, the encoding comprising encoding, by the computing device, a first legacy field, encoding a second legacy field, encoding a third legacy field, and encoding a non-legacy field having at least two symbols, the non-legacy field including a sequence of content bits and a sequence of cyclic redundancy check (CRC) bits; and transmitting the digital communication packet wirelessly.

In addition or in other embodiments of the at least one computer-readable non-transitory storage medium, encoding the non-legacy field can include jointly encoding two symbols of the at least two symbols, the jointly encoded two symbols including the sequence of content bits, the sequence of CRC bits, and a sequence of tail bits.

In addition or in other embodiments of the at least one computer-readable non-transitory storage medium, encoding the non-legacy field comprises jointly encoding two symbols of the at least two symbols, the jointly encoded two symbols including a first sequence of content bits, a first sequence of CRC bits, a second sequence of content bits, a second sequence of CRC bits, and a sequence of tail bits.

In addition or in other embodiments of the at least one computer-readable non-transitory storage medium, encoding the non-legacy field comprises individually encoding a first symbol of the at least one of the two symbols, the individually encoded first symbol including a first sequence of content bits, a first sequence of CRC bits, a second sequence for CRC bits, and a sequence of tail bits.

In certain embodiments, the disclosure can provide an apparatus for wireless communication. The apparatus can include: means for decoding a preamble of a digital communication packet the decoding comprising decoding a field having at least two symbols; means for determining a sequence of content bits based at least on decoding the field; means for determining a first sequence of cyclic redundancy check (CRC) bits based at least on decoding the field; means for determining a second sequence of CRC bits based at least on a portion of the sequence of content bits; means for comparing the first sequence of CRC bits and the second sequence of CRC bits; means for determining that the first sequence of CRC bits and the second sequence of CRC bits match; and means for processing the digital communication packet according to a predetermined radio technology protocol.

In addition or in other embodiments, the apparatus can further include means for determining that the first sequence of CRC bits and the second sequence of CRC bits are a mismatch; and means for processing the digital communication packet according to a second predetermined radio technology protocol.

In addition of in other embodiments of the apparatus, the means for determining the first sequence of CRC bits comprises means for determining a sequence of 12 bits, a sequence of 10 bits, a sequence of eight bits, or a sequence of six bits.

In addition or in other embodiments of the apparatus, the means for determining the first sequence of CRC bits comprises means for determining two sequences of CRC bits received after the sequence of content bits is received.

In addition or in other embodiments of the apparatus, the means for determining the first sequence of CRC bits comprises means for determining the first sequence of CRC bits from two jointly encoded symbols of the at least two symbols.

In addition or in other embodiments of the apparatus, the means for determining the first sequence of CRC bits comprises means for determining the first sequence of CRC bits from a singly encoded symbol of the at least two symbols.

In addition or in other embodiments, the apparatus can further include means for unmasking a fourth sequence of bits obtained from decoding the field prior to determining the second sequence of bits.

In certain embodiments, the disclosure can provide an apparatus for wireless communication. The apparatus can include: means for encoding a digital communication packet, the means for encoding comprising means for encoding a first legacy field, means for encoding a second legacy field, means for encoding a third legacy field, and means for encoding a non-legacy field having at least two symbols, the non-legacy field including a sequence of content bits and a sequence of cyclic redundancy check (CRC) bits; and means for transmitting the digital communication packet wirelessly.

In addition or in other embodiments of the apparatus, the means for encoding the non-legacy field can include means for jointly encoding two symbols of the at least two symbols, the jointly encoded two symbols including the sequence of content bits, the sequence of CRC bits, and a sequence of tail bits.

In addition or in other embodiments of the apparatus, the means for encoding the non-legacy field comprises means for jointly encoding two symbols of the at least two symbols, the jointly encoded two symbols including a first sequence of content bits, a first sequence of CRC bits, a second sequence of content bits, a second sequence of CRC bits, and a sequence of tail bits.

In addition or in other embodiments of the apparatus, the means for encoding the non-legacy field comprises means for individually encoding a first symbol of the at least one of the two symbols, the individually encoded first symbol including a first sequence of content bits, a first sequence of CRC bits, a second sequence for CRC bits, and a sequence of tail bits.

In certain embodiments, the disclosure provides at least one processor-accessible non-transitory storage device having programmed instructions that, in response to execution, cause at least one processor to perform any of the methods described and/or claimed in the present disclosure.

In other embodiments, the disclosure provides at least one processor-accessible non-transitory storage device having programmed instructions that, in response to execution, cause at least one processor to perform a method or realize an apparatus as described in the present disclosure.

In other embodiments, the disclosure provides an apparatus including means for performing a method as described in the present disclosure.

In other embodiments, the disclosure provides an apparatus for wireless communication. The apparatus can include at least one memory device having computer-accessible (or processor-accessible) instructions stored thereon; and at least one processor functionally coupled to the at least one memory device. The at least one processor can be arranged to perform any of the methods described in the present disclosure.

Various embodiments of the disclosure may take the form of an entirely or partially hardware embodiment, an entirely or partially software embodiment, or a combination of software and hardware (e.g., a firmware embodiment). Furthermore, as described herein, various embodiments of the disclosure (e.g., methods and systems) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read only memory (ROM); random access memory (RAM); magnetic disk storage media; optical storage media; flash memory, etc.

Embodiments of the operational environments and techniques (procedures, methods, processes, and the like) are described herein with reference to block diagrams and flowchart illustrations of methods, systems, apparatuses and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general purpose computer, special purpose computer, or other programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification or annexed drawings, or the like.

As used in this application, the terms “component,” “environment,” “system,” “architecture,” “interface,” “unit,” “engine,” “platform,” “module,” and the like are intended to refer to a computer-related entity or an entity related to an operational apparatus with one or more specific functionalities. Such entities may be either hardware, a combination of hardware and software, software, or software in execution. As an example, a component may be, but is not limited to being, a process running on a processor, a processor, an object, an executable portion of software, a thread of execution, a program, and/or a computing device. For example, both a software application executing on a computing device and the computing device can be a component. One or more components may reside within a process and/or thread of execution. A component may be localized on one computing device or distributed between two or more computing devices. As described herein, a component can execute from various computer-readable non-transitory media having various data structures stored thereon. Components can communicate via local and/or remote processes in accordance, for example, with a signal (either analogic or digital) having one or more data packets (e.g., data from one component interacting with another component in a local system, distributed system, and/or across a network such as a wide area network with other systems via the signal). As another example, a component can be an apparatus with specific functionality provided by mechanical parts operated by electric or electronic circuitry that is controlled by a software application or firmware application executed by a processor, wherein the processor can be internal or external to the apparatus and can execute at least a part of the software or firmware application. As yet another example, a component can be an apparatus that provides specific functionality through electronic components without mechanical parts, the electronic components can include a processor therein to execute software or firmware that confers at least in part the functionality of the electronic components. An interface can include input/output (I/O) components as well as associated processor, application, and/or other programming components. The terms “component,” “environment,” “system,” “architecture,” “interface,” “unit,” “engine,” “platform,” “module” can be utilized interchangeably and can be referred to collectively as functional elements.

In the present specification and annexed drawings, reference to a “processor” is made. As utilized herein, a processor can refer to any computing processing unit or device comprising single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit (IC), an application-specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. A processor can be implemented as a combination of computing processing units. In certain embodiments, processors can utilize nanoscale architectures such as, but not limited to, molecular and quantum-dot based transistors, switches and gates, in order to optimize space usage or enhance performance of user equipment.

In addition, in the present specification and annexed drawings, terms such as “store,” storage,” “data store,” “data storage,” “memory,” “repository,” and substantially any other information storage component relevant to operation and functionality of a component of the disclosure, refer to “memory components,” entities embodied in a “memory,” or components forming the memory. It can be appreciated that the memory components or memories described herein embody or comprise non-transitory computer storage media that can be readable or otherwise accessible by a computing device. Such media can be implemented in any methods or technology for storage of information such as computer-readable instructions, information structures, program modules, or other information objects. The memory components or memories can be either volatile memory or non-volatile memory, or can include both volatile and non-volatile memory. In addition, the memory components or memories can be removable or non-removable, and/or internal or external to a computing device or component. Example of various types of non-transitory storage media can comprise hard-disc drives, zip drives, CD-ROM, digital versatile disks (DVD) or other optical storage, magnetic cassettes, magnetic tape, magnetic disk storage or other magnetic storage devices, flash memory cards or other types of memory cards, cartridges, or any other non-transitory medium suitable to retain the desired information and which can be accessed by a computing device.

As an illustration, non-volatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). The disclosed memory components or memories of operational environments described herein are intended to comprise one or more of these and/or any other suitable types of memory.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language generally is not intended to imply that features, elements, and/or operations are in any way required for one or more implementations or that one or more implementations necessarily include logic for deciding, with or without user input or prompting, whether these features, elements, and/or operations are included or are to be performed in any particular implementation.

What has been described herein in the present specification and annexed drawings includes examples of systems, devices, techniques, and computer program products that can provide auto-detection in telecommunications contemplating communication devices that can operate according to different communication protocols (e.g. a new protocol and a legacy protocol). It is, of course, not possible to describe every conceivable combination of elements and/or methods for purposes of describing the various features of the disclosure, but it can be recognized that many further combinations and permutations of the disclosed features are possible. Accordingly, it may be apparent that various modifications can be made to the disclosure without departing from the scope or spirit thereof. In addition or in the alternative, other embodiments of the disclosure may be apparent from consideration of the specification and annexed drawings, and practice of the disclosure as presented herein. It is intended that the examples put forward in the specification and annexed drawings be considered, in all respects, as illustrative and not restrictive. Although specific terms are employed herein, they are used in a generic and descriptive sense only and not for purposes of limitation.

What is claimed is:

1. An apparatus for wireless telecommunication, comprising:
at least one memory device having programmed instructions; and
at least one processor functionally coupled to the at least one memory device and configured to execute the programmed instructions, and in response to execution of the programmed instructions, the at least one processor further configured at least to:
encode a first legacy field of a digital communication packet;
encode a second legacy field of the digital communication packet;
encode a third legacy field of the digital communication packet; and
encode a non-legacy field of the digital communication packet, the non-legacy field having at least two symbols and including a sequence of content bits and a sequence of cyclic redundancy check (CRC) bits.

2. The apparatus of claim 1, wherein the at least processor is further configured to jointly encode two symbols of the at least two symbols, the jointly encoded two symbols including the sequence of content bits, the sequence of CRC bits, and a sequence of tail bits.

3. The apparatus of claim 1, wherein the at least processor is further configured to jointly encode two symbols of the at least two symbols, the jointly encoded two symbols including a first sequence of content bits, a first sequence of CRC bits, a second sequence of content bits, a second sequence of CRC bits, and a sequence of tail bits.

4. The apparatus of claim 1, wherein the at least processor is further configured to encode individually a first symbol of the at least one of the two symbols, the individually encoded first symbol including a first sequence of content bits, a first sequence of CRC bits, a second sequence for CRC bits, and a sequence of tail bits.

5. The apparatus of claim 1, wherein the sequence of CRC bits includes six bits, eight bits, or 12 bits.

6. The apparatus of claim 1, further comprising a radio unit, wherein the at least processor is further configured to send the digital communication packet wirelessly.

7. An apparatus for wireless telecommunication, comprising:
at least one memory device having programmed instructions; and
at least one processor functionally coupled to the at least one memory device and configured to execute the programmed instructions, and in response to execution of the programmed instructions, further configured to:
decode a preamble of a digital communication packet, the preamble comprising a field having at least two symbols;
determine a sequence of content bits based at least on the decoded preamble;
determine a first sequence of cyclic redundancy check (CRC) bits based at least on the decoded field;
determine a second sequence of CRC bits based at least on a portion of the sequence of content bits;
compare the first sequence of CRC bits and the second sequence of CRC bits;
determine that the first sequence of CRC bits and the second sequence of CRC bits match; and
process the at least one packet in accordance with a predetermined radio technology protocol.

8. The apparatus of claim 7, wherein the at least one processor is further configured to determine that the first sequence of CRC bits and the second sequence of CRC bits are a mismatch; and
to process the digital communication packet according to a second predetermined radio technology protocol.

9. The apparatus of claim 7, wherein the at least one processor is further configured to determine a sequence of 12 CRC bits, a sequence of 10 CRC bits, a sequence of eight CRC bits, or a sequence of six CRC bits.

10. The apparatus of claim 8, wherein the at least one processor is further configured to determine the first sequence of CRC bits from two jointly encoded symbols of the at least two symbols.

11. The apparatus of claim 7, wherein the at least one processor is further configured to determine the first sequence of CRC bits from a singly encoded symbol of the at least two symbols.

12. The apparatus of claim 7, wherein the at least one processor is further configured to determine a mask for the first sequence of CRC bits.

13. A method for wireless communication, comprising:
decoding, by a computing device comprising one or more processors coupled to one or more memory devices, a preamble of a digital communication packet the decoding comprising decoding a field having at least two symbols;
determining, by the computing device, a sequence of content bits based at least on decoding the field;
determining, by the computing device, a first sequence of cyclic redundancy check (CRC) bits based at least on decoding the field;
determining, by the computing device, a second sequence of CRC bits based at least on a portion of the sequence of content bits;
comparing, by the computing device, the first sequence of CRC bits and the second sequence of CRC bits;
determining, by the computing device, that the first sequence of CRC bits and the second sequence of CRC bits match; and
processing, by the computing device, the digital communication packet according to a predetermined radio technology protocol.

14. The method of claim 13, further comprising determining, by the computing device, that the first sequence of CRC bits and the second sequence of CRC bits are a mismatch; and processing, by the computing device, the digital communication packet according to a second predetermined radio technology protocol.

15. The method of claim 13, wherein determining the first sequence of CRC bits comprises determining, by the computing device, a sequence of 12 bits, a sequence of 10 bits, a sequence of eight bits, or a sequence of six bits.

16. The method of claim 13, wherein determining the first sequence of CRC bits comprises determining, by the computing device, two sequences of CRC bits received after the sequence of content bits is received.

17. The method of claim 13, wherein determining the first sequence of CRC bits comprises determining, by the computing device, the first sequence of CRC bits from two jointly encoded symbols of the at least two symbols.

18. The method of claim 13, wherein determining the first sequence of CRC bits comprises determining, by the computing device, the first sequence of CRC bits from a singly encoded symbol of the at least two symbols.

19. The method of claim 13, further comprising unmasking, by the computing device, a fourth sequence of bits obtained from decoding the field prior to determining the second sequence of bits.

20. A method for wireless communication, comprising:
encoding, by a computing device comprising one or more processors coupled to one or more memory devices, a digital communication packet, the encoding comprising:
encoding, by the computing device, a first legacy field;
encoding, by the computing device, a second legacy field;
encoding, by the computing device, a third legacy field; and
encoding, by the computing device, a non-legacy field having at least two symbols, the non-legacy field including a sequence of content bits and a sequence of cyclic redundancy check (CRC) bits.

21. The method of claim 20, wherein encoding the non-legacy field comprises jointly encoding, by the computing device, two symbols of the at least two symbols, the jointly encoded two symbols including the sequence of content bits, the sequence of CRC bits, and a sequence of tail bits.

22. The method of claim 20, wherein encoding the non-legacy field comprises jointly encoding, by the computing device, two symbols of the at least two symbols, the jointly encoded two symbols including a first sequence of content bits, a first sequence of CRC bits, a second sequence of content bits, a second sequence of CRC bits, and a sequence of tail bits.

23. The method of claim 20, wherein encoding the non-legacy field comprises individually encoding, by the computing device, a first symbol of the at least one of the two symbols, the individually encoded first symbol including a first sequence of content bits, a first sequence of CRC bits, a second sequence for CRC bits, and a sequence of tail bits.

24. The method of claim 20, further comprising sending, by the computing device, the digital communication packet wirelessly.
